(19) United States
(12) Patent Application Publication
(10) Pub. No.: US 2026/0150664 A1
(43) Pub. Date: May 28, 2026

(54) INTEGRATED DEVICE COMPRISING AN INDUCTOR

(71) Applicant: QUALCOMM Incorporated, San Diego, CA (US)

(72) Inventors: Hsiao-Tsung YEN, San Diego, CA (US); Yangyang SUN, San Diego, CA (US); Yujen CHEN, Taichung (TW)

(21) Appl. No.: 18/957,462

(22) Filed: Nov. 22, 2024

(51) Int. Cl. H01L 23/522; H01L 23/00; H01L 23/31

(52) U.S. Cl. CPC H10W 20/497; H10D 1/20; H10W 74/114; H10W 72/934; H10W 80/732

(57) ABSTRACT

A package comprising an integrated device and a substrate coupled to the integrated device through a plurality of solder interconnects. The integrated device comprises a die substrate; a die interconnection portion coupled to the die substrate; a plurality of pad interconnects coupled to the die interconnection portion; a plurality of pillar interconnects coupled to the plurality of pad interconnects; and a plurality of interconnects coupled to the plurality of pillar interconnects, wherein at least one pad interconnect from the plurality of pad interconnects, at least one pillar interconnects from the plurality of pillar interconnects and at least one interconnect from the plurality of interconnects are configured as an inductor.

### FIELD

Various features relate to packages and integrated devices.

### BACKGROUND

A package may include a substrate and integrated devices. These components are coupled together to provide a package that may perform various electrical functions. There is an ongoing need to provide better performing packages, including providing better performing integrated devices Moreover, there is also an ongoing need to reduce and/or minimize the overall size of the packages.

### SUMMARY

Various features relate to packages and integrated devices.

One example provides an integrated device that comprises a die substrate; a die interconnection portion coupled to the die substrate; a plurality of pad interconnects coupled to the die interconnection portion; a plurality of pillar interconnects coupled to the plurality of pad interconnects; and a plurality of interconnects coupled to the plurality of pillar interconnects, wherein at least one pad interconnect from the plurality of pad interconnects, at least one pillar interconnects from the plurality of pillar interconnects and at least one interconnect from the plurality of interconnects are configured as an inductor.

Another example provides a package comprising an integrated device and a substrate coupled to the integrated device through a plurality of solder interconnects. The integrated device comprises a die substrate; a die interconnection portion coupled to the die substrate; a plurality of pad interconnects coupled to the die interconnection portion; a plurality of pillar interconnects coupled to the plurality of pad interconnects; and a plurality of interconnects coupled to the plurality of pillar interconnects, wherein at least one pad interconnect from the plurality of pad interconnects, at least one pillar interconnects from the plurality of pillar interconnects and at least one interconnect from the plurality of interconnects are configured as an inductor.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates an exemplary integrated device that comprises an inductor.

FIG. 2 illustrates an exemplary cross sectional profile view of an integrated device that comprises an inductor.

FIG. 3 illustrates an exemplary plan view of an integrated device that comprises an inductor.

FIG. 4 illustrates an exemplary cross sectional profile view of an integrated device that comprises an inductor.

FIG. 5 illustrates an exemplary plan view of an integrated device that comprises an inductor.

FIG. 6 illustrates an exemplary cross sectional profile view of an integrated device that comprises an inductor.

FIG. 7 illustrates an exemplary cross sectional profile view of an integrated device that comprises an inductor.

FIG. 8 illustrates an exemplary cross sectional profile view of a package comprising an integrated device that comprises an inductor.

FIG. 9 illustrates an exemplary cross sectional profile view of a package comprising an integrated device that comprises an inductor.

FIG. 10 illustrates an exemplary plan view of a design of an inductor for an integrated device.

FIG. 11 illustrates an exemplary plan view of a design of an inductor for an integrated device.

FIG. 12 illustrates an exemplary plan view of a design of a transformer for an integrated device.

FIGS. 13A-13F illustrate an exemplary sequence for fabricating an integrated device comprising an inductor.

FIGS. 14A-14G illustrate an exemplary sequence for fabricating an integrated device comprising an inductor.

FIG. 15 illustrates an exemplary flow chart of a method for fabricating an integrated device comprising an inductor.

FIG. 16 illustrates an exemplary flow chart of a method for fabricating an integrated device comprising an inductor.

FIG. 17 illustrates various electronic devices that may integrate a die, an electronic circuit, an integrated device, an integrated passive device (IPD), a passive component, a package, and/or a device package described herein.

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown as block diagrams in order to avoid obscuring the aspects in unnecessary detail. In other instances, well-known circuits, structures and techniques may not be shown in detail in order not to obscure the aspects of the disclosure.

The present disclosure describes a package comprising an integrated device and a substrate coupled to the integrated device through a plurality of solder interconnects. The integrated device comprises a die substrate; a die interconnection portion coupled to the die substrate; a plurality of pad interconnects coupled to the die interconnection portion; a plurality of pillar interconnects coupled to the plurality of pad interconnects; and a plurality of interconnects coupled to the plurality of pillar interconnects, wherein at least one pad interconnect from the plurality of pad interconnects, at least one pillar interconnects from the plurality of pillar interconnects and at least one interconnect from the plurality of interconnects are configured as an inductor. The integrated device may include a high quality factor inductor that has low magnetic coupling with a nearby inductor.

### Exemplary Integrated Device Comprising an Inductor

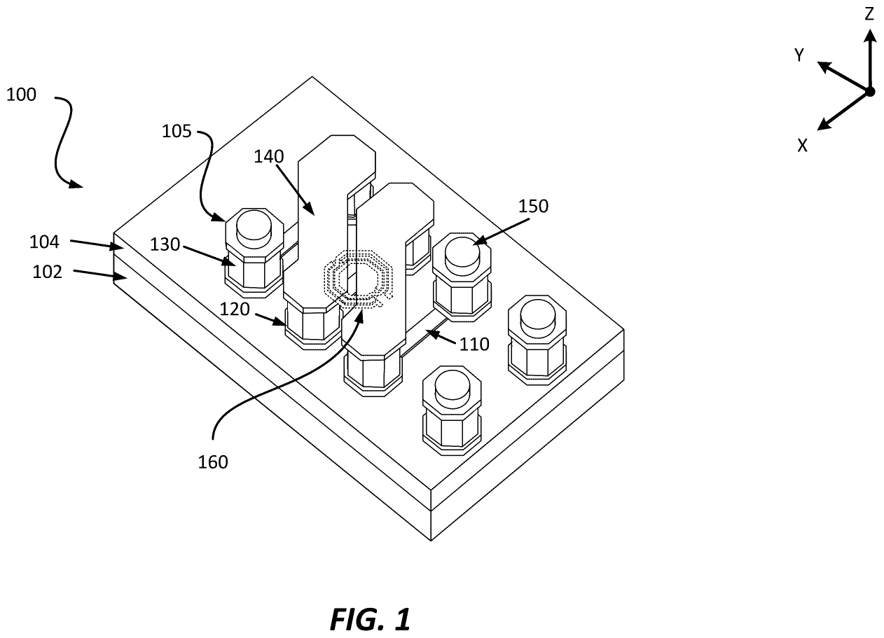

FIG. 1 illustrates an integrated device 100 that includes a die substrate 102, a die interconnection portion 104, a plurality of die interconnects 110, a plurality of pad interconnects 120, a plurality of pillar interconnects 130, a plurality of interconnects 140 and a plurality of solder interconnects 150. The plurality of die interconnects 110 may be coupled to and touch the plurality of pad interconnects 120. The plurality of pad interconnects 120 may be coupled to and touch the plurality of pillar interconnects 130. The plurality of pillar interconnects 130 may be coupled to and touch the plurality of interconnects 140. The plurality of interconnects 140 may be coupled to and touch the plurality of solder interconnects 150.

The integrated device 100 may also include an inductor 160. The inductor 160 may be located in the die interconnection portion 104. The inductor 160 may be define by die interconnects of the die interconnection portion 104. The integrated device 100 includes an inductor 105. The inductor 105 may be defined by die interconnects from the plurality of die interconnects 110, pad interconnects from the plurality of pad interconnects 120, pillar interconnects from the plurality of pillar interconnects 130, and/or interconnects from the plurality of interconnects 140. The inductor 105 may be configured as a solenoid inductor. The inductor 160 may be located in the die interconnection portion 104. The inductor 160 may be located vertically between the die substrate 102 and the inductor 105. The location of the inductor 105 helps provide an inductor that has high impedance that can fit and/or be part of the integrated device 100. Different examples of inductors in an integrated device and/or a package will now be further described below.

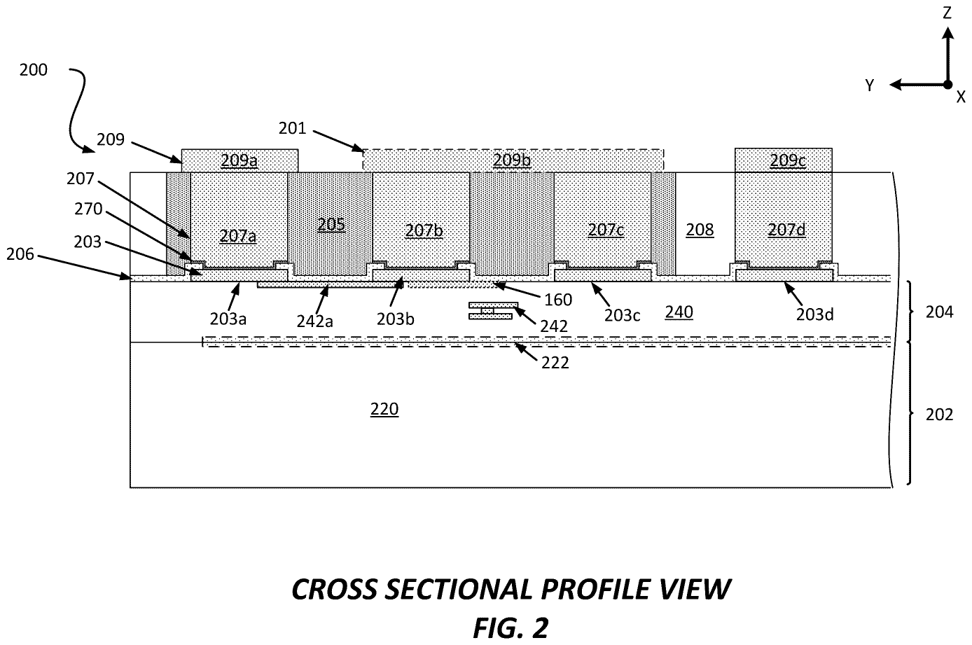

FIG. 2 illustrates a cross sectional profile view of an integrated device 200 that includes an inductor. The integrated device 200 includes a die substrate portion 202, and a die interconnection portion 204. The die substrate portion 202 includes a die substrate 220 and an active region 222. The active region 222 may include a plurality of logic cells, a plurality of transistors, and/or a plurality of filters. Different implementations may use different types of transistors, such as a field effect transistor (FET), planar FET, finFET, and a gate all around FET. In some implementations, a front end of line (FEOL) process may be used to fabricate the active region 222 of the die substrate 220. The die substrate 220 may include silicon.

The die interconnection portion 204 includes at least one dielectric layer 240 and a plurality of die interconnects 242. The die interconnection portion 204 is coupled to the die substrate portion 202. The plurality of die interconnects 242 are coupled to the active region 222 of the die substrate portion 202. In some implementations, a back end of line (BEOL) process may be used to fabricate the die interconnection portion 204. The die interconnection portion 204 includes the inductor 160. The inductor 160 may be define by die interconnects from the plurality of die interconnects 242. The inductor 160 may be located on one or more metal layers of the die interconnection portion 204. The inductor 160 may be located on any metal layer(s) of the die interconnection portion 204. The inductor 160 may be located vertically between an inductor 201 and the die substrate 220.

The integrated device 200 includes a plurality of pad interconnects 203 and a passivation layer 206. The plurality of pad interconnects 203 and/or the passivation layer 206 may be coupled to the die interconnection portion 204. The plurality of pad interconnects 203 are coupled to the plurality of die interconnects 242. In some implementations, the plurality of pad interconnects 203 and/or the passivation layer 206 may be considered part of the die interconnection portion 204. The plurality of pad interconnects 203 include a pad interconnect 203a, a pad interconnect 203b, a pad interconnect 203c and a pad interconnect 203d.

The integrated device 200 includes a plurality of pillar interconnects 207, a plurality of interconnects 209, a magnetic layer 205 and an encapsulation layer 208. The plurality of pillar interconnects 207 include a pillar interconnect 207a, a pillar interconnect 207b, a pillar interconnect 207c and a pillar interconnect 207d. The plurality of interconnects 209 include an interconnect 209a, an interconnect 209b, an interconnect 209c and an interconnect 209d. The plurality of pillar interconnects 207 may be coupled to and touch the plurality of pad interconnects 203. The plurality of interconnects 209 may be coupled to and touch the plurality of pillar interconnects 207. The plurality of pillar interconnects 207 may include a seed layer 270. The seed layer 270 may be an under bump metallization interconnect. In some implementations, the under bump metallization interconnect may be considered part of the plurality of pillar interconnects 207.

The magnetic layer 205 may at least laterally surround some of the pillar interconnects from the plurality of pillar interconnects 207. For example, the magnetic layer 205 may at least laterally surround the pillar interconnect 207a, the pillar interconnect 207b and/or the pillar interconnect 207c. The encapsulation layer 208 may at least partially encapsulate the magnetic layer 205 and/or pillar interconnects from the plurality of pillar interconnects 207. For example, the encapsulation layer 208 may at least partially encapsulate the pillar interconnect 207d. The magnetic layer 205 may be coupled to and touch the passivation layer 206. The encapsulation layer 208 may be coupled to and touch the passivation layer 206. The encapsulation layer 208 may include a mold, a resin, an epoxy and/or a filler.

The magnetic layer 205 may include one or more magnetic layers. The magnetic layer 205 includes an insulating layer, a dielectric layer and/or a non-electrical conducting material (e.g., material that does not electrically conduct). The magnetic layer 205 may be both a dielectric material and a magnetic material. Thus, the magnetic layer 205 may have both dielectric properties and magnetic properties. The magnetic layer 205 may include one or more materials. The magnetic layer 205 has a permeability value that is greater than 1 (e.g., about 10 or greater, range of 6-12). The magnetic layer 205 may have different permeability values at different frequencies. The permeability value of a magnetic material and/or a magnetic layer, as described in the disclosure is a relative permeability value that is defined as a ratio of the permeability of a material to the permeability of free space. Thus, the permeability values that are described for the magnetic materials and/or magnetic layers that are illustrated and/or described in the disclosure may represent a relative permeability value that is relative to a defined permeability value (e.g., reference permeability value) of free space. In some implementations, free space may be defined to have a defined permeability value of μ₀=4π×10⁻⁷ H/m (Henry per meter). A material that has a relative permeability value that is greater than 1 may be considered to be a magnetic material. Similarly, a material layer that has a relative permeability value that is greater than 1 may be considered to be a magnetic layer. The magnetic layer 205 may include a magnetic loss tangent value that is in a range of about 0.01-0.04. For example, the at least one magnetic layer may include a magnetic loss tangent value that is in a range of about 0.01-0.04 for frequencies up to 100 MHz. The magnetic layer 205 may include may include various magnetic materials. For example, the at least one magnetic layer 230 may include Ajinomoto Magnetic Film (AMF). The magnetic layer 205 is configured to improve the inductance and/or quality factor of an inductor that is located in and/or surrounded by the magnetic layer 205. With improved inductor performance, smaller and more compact inductors may be formed in the integrated device.

In some implementations, pad interconnects from the plurality of pad interconnects 203, pillar interconnects from the plurality of pillar interconnects 207 and/or interconnects from the plurality of interconnects 209 may define an inductor 201. In some implementations, die interconnects from the plurality of die interconnects 242, pad interconnects from the plurality of pad interconnects 203, pillar interconnects from the plurality of pillar interconnects 207 and/or interconnects from the plurality of interconnects 209 may define an inductor 201. The inductor 201 may be a solenoid inductor.

The inductor 201 may be define by the die interconnect 242a, the pad interconnect 203a, the pad interconnect 203b, the pad interconnect 203c, the pillar interconnect 207a, the pillar interconnect 207b, the pillar interconnect 207c, the interconnect 209a and the interconnect 209b. The interconnect 209a may be coupled to and touch the pillar interconnect 207a. The pillar interconnect 207a may be coupled to and touch the pad interconnect 203a. The pad interconnect 203a may be coupled to and touch the die interconnect 242a. The die interconnect 242a may be coupled to and touch the pad interconnect 203b. The pad interconnect 203b may be coupled to and touch the pillar interconnect 207b. The pillar interconnect 207b may be coupled to and touch the interconnect 209b. The interconnect 209b may be coupled to and touch the pillar interconnect 207c. The pillar interconnect 207c may be coupled to and touch the pad interconnect 203c. The inductor 201 may have a high quality factor and may have a low magnetic coupling with the inductor 160.

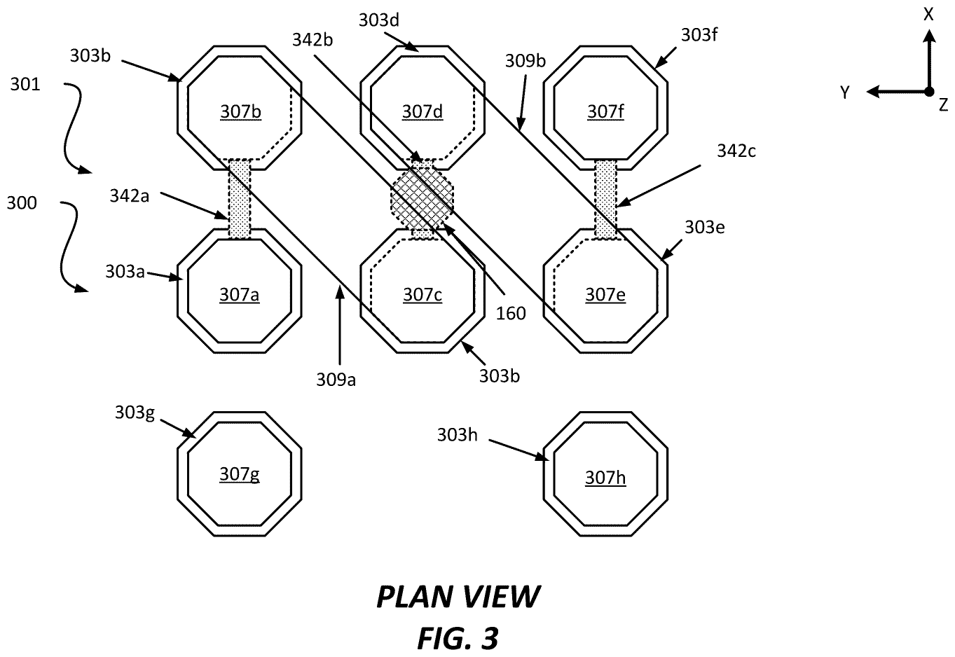

FIG. 3 illustrates an exemplary plan view of an integrated device 300 comprising an inductor 301. The inductor 301 may represent the inductor 201 of the integrated device 200 of FIG. 2. The inductor 301 may be defined by a die interconnect 342a, a die interconnect 342b, a die interconnect 342c, a pad interconnect 303a, a pad interconnect 303b, a pad interconnect 303c, a pad interconnect 303d, a pad interconnect 303e, a pad interconnect 303f, a pillar interconnect 307a, a pillar interconnect 307b, a pillar interconnect 307c, a pillar interconnect 307d, a pillar interconnect 307e, a pillar interconnect 307f, an interconnect 309a and an interconnect 309b. The inductor 301 may be configured to be coupled to power. Different implementations may have different numbers of turns for the inductor 301, different numbers of die interconnects, different numbers of pad interconnects, different numbers of pillar interconnects and/or different numbers of interconnects.

The integrated device 300 includes an inductor 160. The inductor 160 may be defined by die interconnects of the die interconnection portion of the integrated device 300. The integrated device 300 includes a pad interconnect 303g, a pillar interconnect 307g, a pad interconnect 30h and a pillar interconnect 307h. The pad interconnect 303g and the pillar interconnect 307g are configured to provide an electrical path for a signal. The pad interconnect 303h and the pillar interconnect 307h are configured to provide an electrical path for another signal.

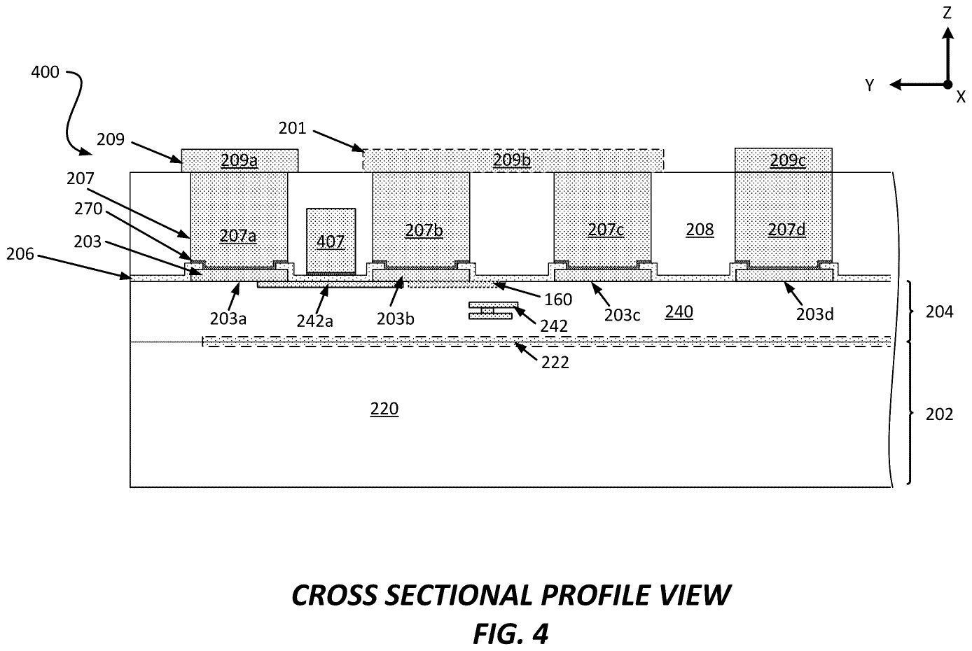

FIG. 4 illustrates a cross sectional profile view of an integrated device 400 that includes an inductor. The integrated device 400 is similar to the integrated device 200. The integrated device 400 includes similar components as the integrated device 200. The integrated device 400 includes a die substrate portion 202, a die interconnection portion 204, a plurality of pad interconnects 203, a passivation layer 206, a plurality of pillar interconnect 207, a plurality of interconnects 209, a block component 407 and an encapsulation layer 208. The die substrate portion 202, the die interconnection portion 204, the plurality of pad interconnects 203, the passivation layer 206, the plurality of pillar interconnect 207, the plurality of interconnects 209 and/or the encapsulation layer 208 may be arranged in a similar manner as described for the integrated device 200.

The block component 407 may include one or more block components. The block component 407 may include a metal (e.g., at least one metal structure). The block component 407 may be surrounded by the inductor 201. The block component 407 may be located within the windings of the inductor 201. The block components 407 may be located in different locations of the integrated device 400. The block component 407 may include a seed layer 270. The block component 407 may be coupled to the passivation layer 206. The encapsulation layer 208 may at least partially encapsulate the block component 407. The block component 407 may not be electrically coupled to the inductor 201 and/or other interconnects in the integrated device 400. The block component 407 may include nickel (Ni). In some implementations, the block component 407 may include a magnetic material. In some implementations, the block component 407 may be a magnetic dummy component. For example, the block component 407 is not electrically touching other electrical components.

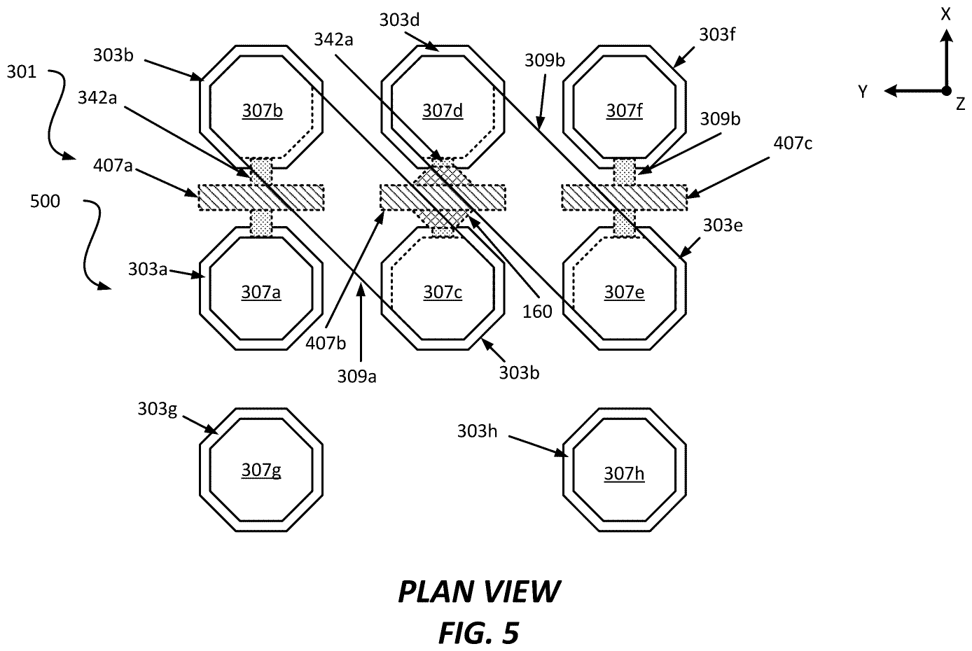

FIG. 5 illustrates an exemplary plan view of an integrated device 500 comprising an inductor 301. The inductor 301 may represent the inductor 201 of the integrated device 400 of FIG. 4. The integrated device 500 includes a block component 407a, a block component 407b and a block component 407c. The inductor 301 may be defined by a die interconnect 342a, a die interconnect 342b, a die interconnect 342c, a pad interconnect 303a, a pad interconnect 303b, a pad interconnect 303c, a pad interconnect 303d, a pad interconnect 303e, a pad interconnect 303f, a pillar interconnect 307a, a pillar interconnect 307b, a pillar interconnect 307c, a pillar interconnect 307d, a pillar interconnect 307e, a pillar interconnect 307f, an interconnect 309a and an interconnect 309b. The inductor 301 may be configured to be coupled to power. Different implementations may have different numbers of turns for the inductor 301, different numbers of die interconnects, different numbers of pad interconnects, different numbers of pillar interconnects and/or different numbers of interconnects. The block component 407a, the block component 407b and/or the block component 407c may be located within the windings of the inductor 301. Different implementations may have different numbers of block components, different shapes of block components and/or different sizes of block components. The inductor 301 may have a high quality factor and may have a low magnetic coupling with the inductor 160.

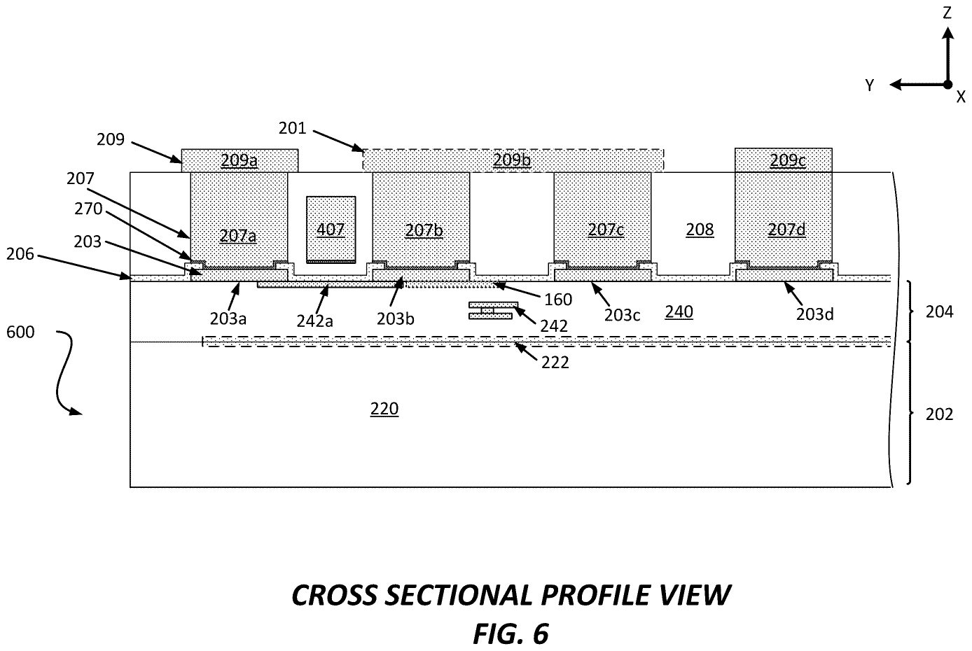

FIG. 6 illustrates a cross sectional profile view of an integrated device 600 that includes an inductor. The integrated device 600 is similar to the integrated device 400. The integrated device 600 includes similar components as the integrated device 200 and/or the integrated device 400. The integrated device 600 includes a die substrate portion 202, a die interconnection portion 204, a plurality of pad interconnects 203, a passivation layer 206, a plurality of pillar interconnect 207, a plurality of interconnects 209, a block component 407 and an encapsulation layer 208. The die substrate portion 202, the die interconnection portion 204, the plurality of pad interconnects 203, the passivation layer 206, the plurality of pillar interconnect 207, the plurality of interconnects 209 and/or the encapsulation layer 208 may be arranged in a similar manner as described for the integrated device 200 and/or the integrated device 400.

The block component 407 is located within the windings of the inductor 201. However, the block component 407 is not directly touching the passivation layer 206. The encapsulation layer 208 may encapsulate the block component 407. The block component 407 may include a seed layer 270. In some implementations, the block component 407 may be a magnetic dummy component. For example, the block component 407 is not electrically touching other electrical components.

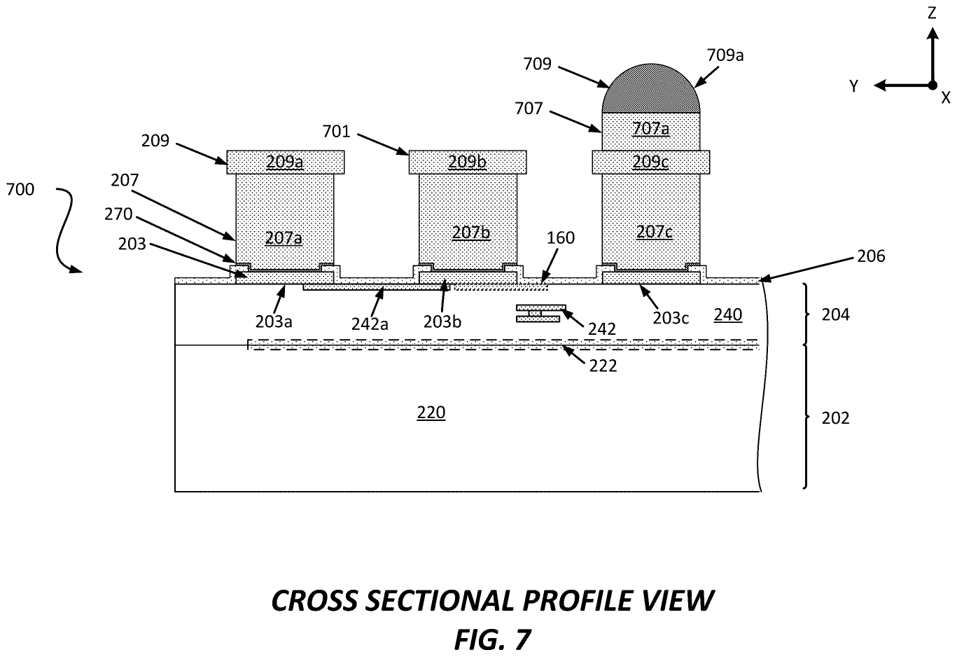

FIG. 7 illustrates a cross sectional profile view of an integrated device 700 that includes an inductor. The integrated device 700 is similar to the integrated device 200. The integrated device 700 includes similar components as the integrated device 200. The integrated device 700 includes a die substrate portion 202, a die interconnection portion 204, a plurality of pad interconnects 203, a passivation layer 206, a plurality of pillar interconnect 207, and a plurality of interconnects 209. The die substrate portion 202, the die interconnection portion 204, the plurality of pad interconnects 203, the passivation layer 206, the plurality of pillar interconnect 207, and/or the plurality of interconnects 209 may be arranged in a similar manner as described for the integrated device 200. The integrated device 700 may also include a plurality of interconnects 707 and a plurality of solder interconnects 709.

In some implementations, pad interconnects from the plurality of pad interconnects 203, pillar interconnects from the plurality of pillar interconnects 207 and/or interconnects from the plurality of interconnects 209 may define an inductor 201. In some implementations, die interconnects from the plurality of die interconnects 242, pad interconnects from the plurality of pad interconnects 203, pillar interconnects from the plurality of pillar interconnects 207 and/or interconnects from the plurality of interconnects 209 may define an inductor 701. The inductor 701 may be a solenoid inductor.

The inductor 701 may be define by the die interconnect 242a, the pad interconnect 203a, the pad interconnect 203b, the pillar interconnect 207a, the pillar interconnect 207b, the interconnect 209a and the interconnect 209b. The interconnect 209a may be coupled to and touch the pillar interconnect 207a. The pillar interconnect 207a may be coupled to and touch the pad interconnect 203a. The pad interconnect 203a may be coupled to and touch the die interconnect 242a. The die interconnect 242a may be coupled to and touch the pad interconnect 203b. The pad interconnect 203b may be coupled to and touch the pillar interconnect 207b. The pillar interconnect 207b may be coupled to and touch the interconnect 209b. The pillar interconnect 207c may be coupled to and touch the pad interconnect 203c. The interconnect 707a may be coupled to and touch the interconnect 209c. The solder interconnect 709a may be coupled to and touch the interconnect 707a.

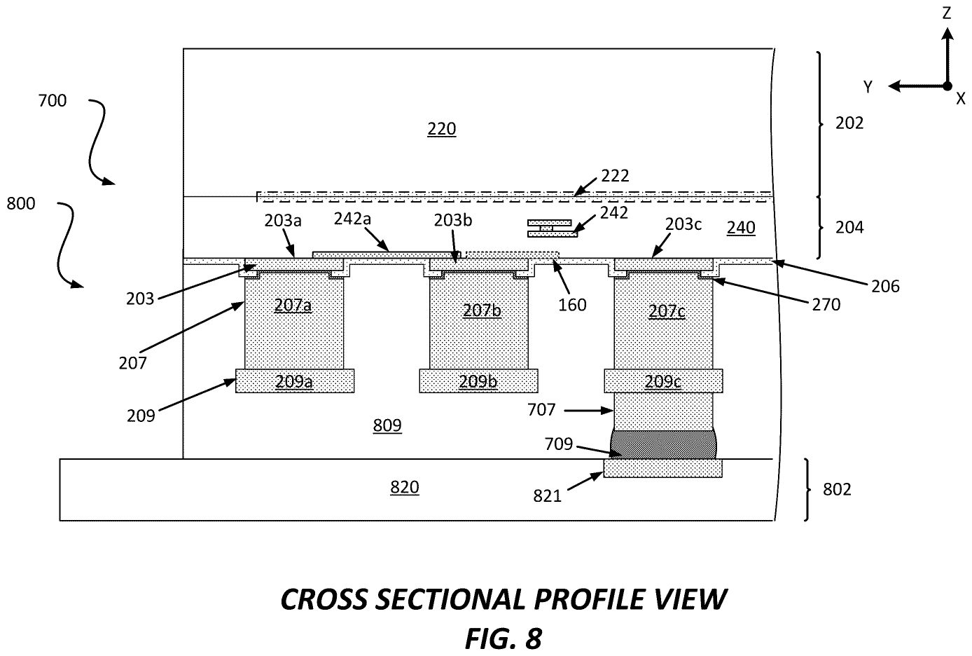

FIG. 8 illustrates a package 800 that includes an integrated device 700 and a substrate 802. The substrate 802 may be a laminated substrate (e.g., coreless substate, cored substrate). The substrate 802 includes at least one dielectric layer 820 and a plurality of interconnects 821. The integrated device 700 is coupled to the substrate 802 through the plurality of solder interconnects 709. The plurality of solder interconnects 709 may be coupled to and touching the plurality of interconnects 821. The package 800 may include an underfill located between the integrated device 700 and the substrate 802.

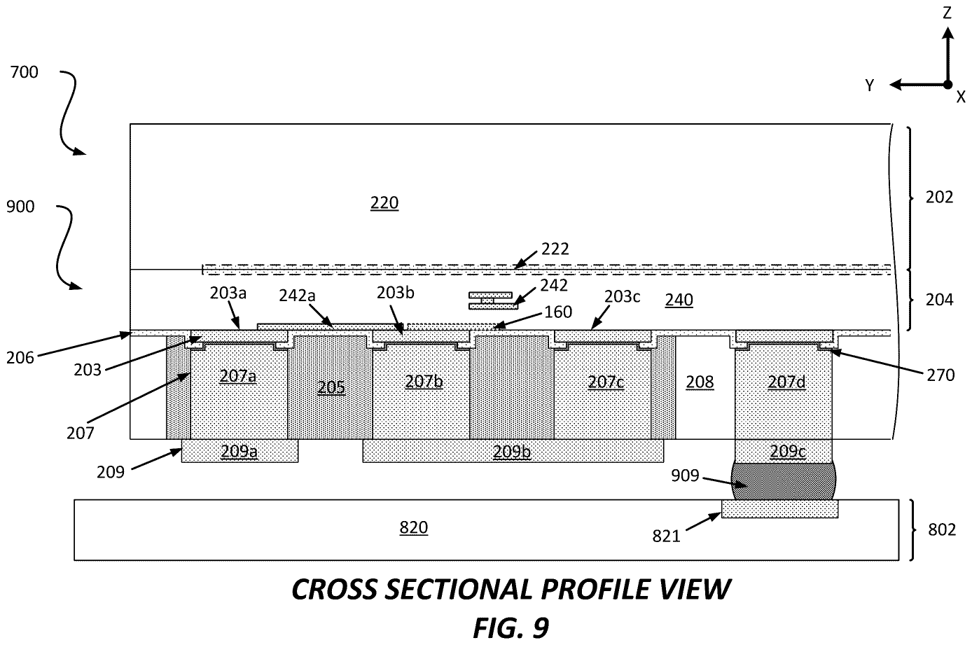

FIG. 9 illustrates a package 900 that includes an integrated device 200 and a substrate 802. The substrate 802 may be a laminated substrate (e.g., coreless substate, cored substrate). The substrate 802 includes at least one dielectric layer 820 and a plurality of interconnects 821. The integrated device 200 is coupled to the substrate 802 through the plurality of solder interconnects 909. The plurality of solder interconnects 909 may be coupled to and touching the plurality of interconnects 821 and some interconnects form the plurality of interconnects 209.

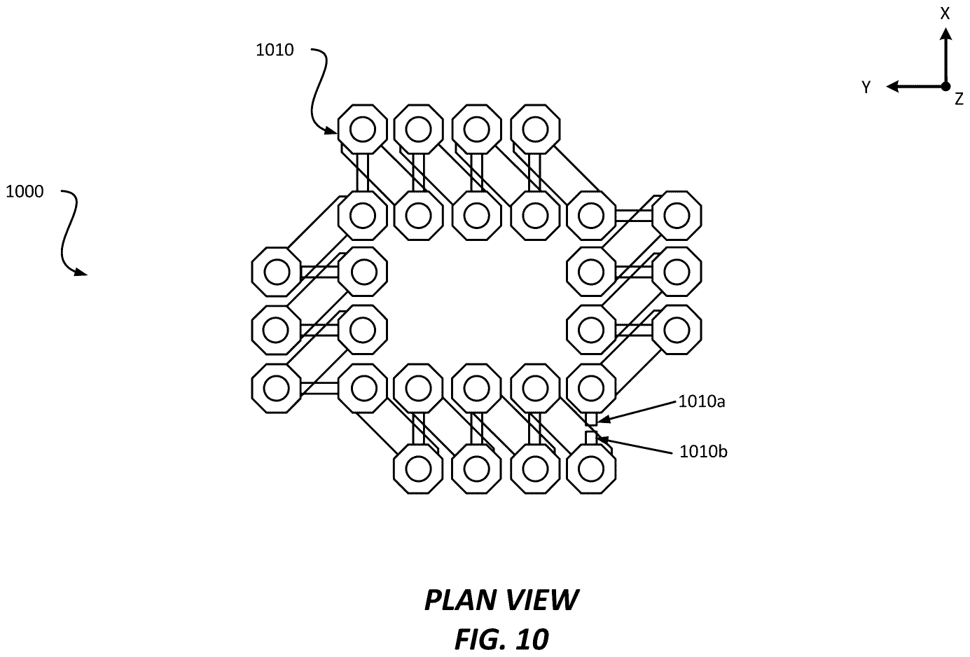

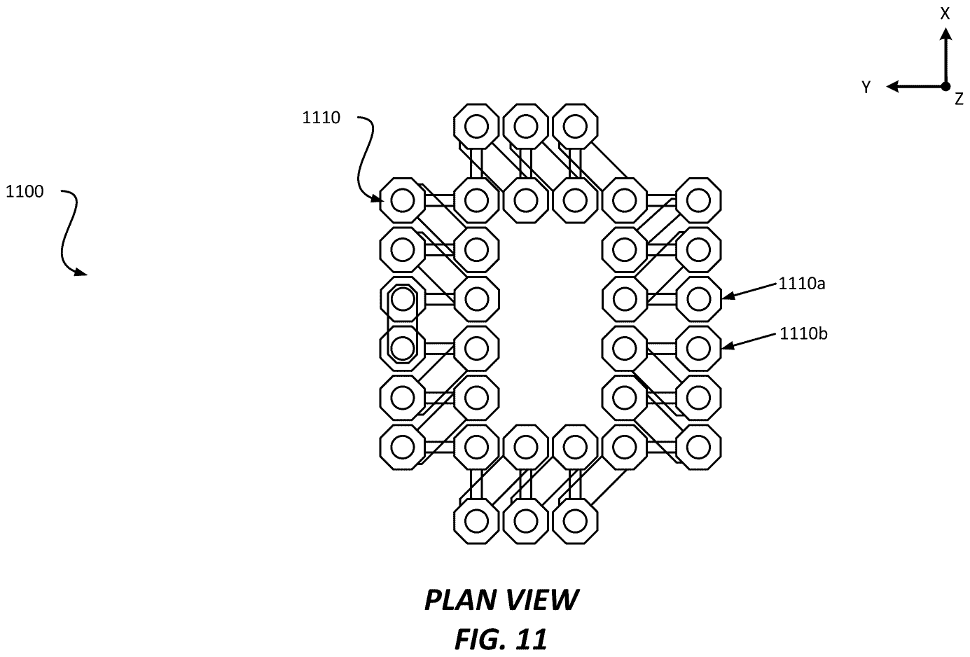

FIGS. 10-12 illustrate different inductor designs and/or configurations that may be implemented in an integrated device. FIG. 10 illustrates an inductor 1000 that is configured as a solenoid inductor with a circular type planar cross section. The inductor 1000 includes a plurality of interconnects 1010. The plurality of interconnects 1010 may represent any of the interconnects (e.g., pad interconnects, via interconnects, pillar interconnects) described in the disclosure that is used to form and/or define an inductor. The inductor 1000 may include a first terminal and second terminal. The first terminal and the second terminal of the inductor 1000 may be any of the interconnects from the plurality of interconnects 1010. For example, interconnect 1010a may be a first terminal of the inductor 1000, and interconnect 1010b may be a second terminal of the inductor 1000. FIG. 11 illustrates an inductor 1100 that is configured as a solenoid inductor. The inductor 1100 includes a plurality of interconnects 1110. The plurality of interconnects 1110 may represent any of the interconnects (e.g., pad interconnects, via interconnects, pillar interconnects) described in the disclosure that is used to form and/or define an inductor. The inductor 1100 may include a first terminal and second terminal. The first terminal and the second terminal of the inductor 1100 may be any of the interconnects from the plurality of interconnects 1110. For example, interconnect 1110a may be a first terminal of the inductor 1100, and interconnect 1110b may be a second terminal of the inductor 1100.

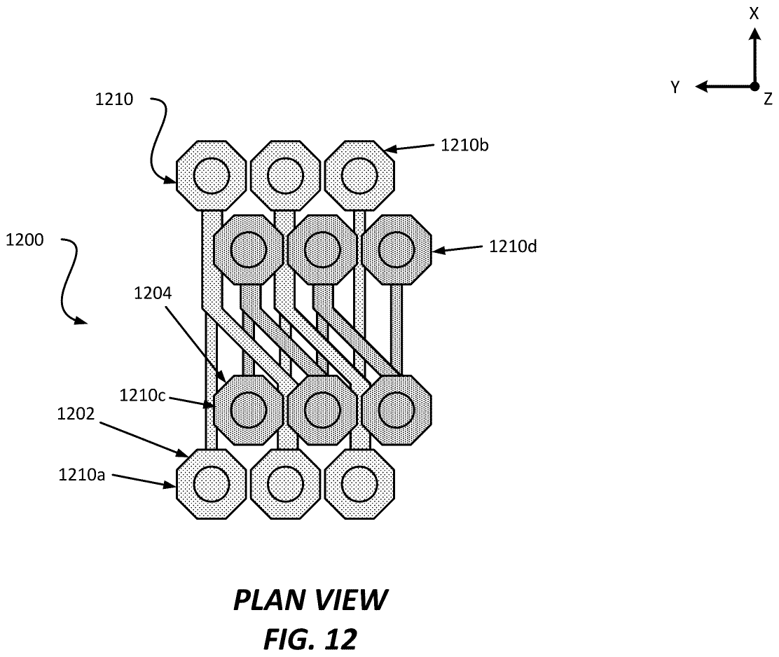

FIG. 12 illustrates a transformer 1200 that includes two inductors that are intertwined. The transformer 1200 includes an inductor 1202 and an inductor 1204. The inductor 1202 may be a first solenoid inductor. The inductor 1204 may be a second solenoid inductor. The inductor 1204 is intertwined with the inductor 1202. The transformer 1200 includes a plurality of interconnects 1210. The plurality of interconnects 1210 may represent any of the interconnects (e.g., pad interconnects, via interconnects, pillar interconnects) described in the disclosure that is used to form and/or define an inductor. The inductor 1202 may include a first terminal and second terminal. For example, interconnect 1210a may be a first terminal of the inductor 1202, and interconnect 1210b may be a second terminal of the inductor 1202. The inductor 1204 may include a first terminal and second terminal. For example, interconnect 1210c may be a first terminal of the inductor 1204, and interconnect 1210d may be a second terminal of the inductor 1204. FIG. 12 illustrates an exemplary conceptual representation of the transformer 1200. As such, the interconnects may be located on different metal layers of the integrated devices, and may be intertwined differently from what is shown in FIG. 12. The inductor 1000, the inductor 1100 and/or the transformer 1200 may include different shapes, different sizes, different configurations and/or different configurations.

An integrated device (e.g., 100, 200) may include a die (e.g., semiconductor bare die). The integrated device may include a power management integrated circuit (PMIC). The integrated device may include an application processor. The integrated device may include a modem. The integrated device may include a radio frequency (RF) device, a passive device, a filter, a capacitor, an inductor, an antenna, a transmitter, a receiver, a gallium arsenide (GaAs) based integrated device, a surface acoustic wave (SAW) filter, a bulk acoustic wave (BAW) filter, a light emitting diode (LED) integrated device, a silicon (Si) based integrated device, a silicon carbide (SiC) based integrated device, a memory, power management processor, and/or combinations thereof. An integrated device may include at least one electronic circuit (e.g., first electronic circuit, second electronic circuit, etc...). An integrated device may include an input/output (I/O) hub. An integrated device may include transistors. An integrated device may be an example of an electrical component and/or electrical device.

In some implementations, an integrated device may be a chiplet. A chiplet may be fabricated using a process that provides better yields compared to other processes used to fabricate other types of integrated devices, which can lower the overall cost of fabricating a chiplet. Different chiplets may have different sizes and/or shapes. Different chiplets may be configured to provide different functions. Different chiplets may have different interconnect densities (e.g., interconnects with different width and/or spacing). In some implementations, several chiplets may be used to perform the functionalities of one or more chips (e.g., one more integrated devices). As mentioned above, using several chiplets that perform several functions may reduce the overall cost of a package relative to using a single chip to perform all of the functions of a package. In some implementations, one or more of the chiplets and/or one of more of integrated devices (e.g., 100, 200) described in the disclosure may be fabricated using the same technology node or two or more different technology nodes. For example, an integrated device may be fabricated using a first technology node, and a chiplet may be fabricated using a second technology node that is not as advanced as the first technology node. In such an example, the integrated device may include components (e.g., interconnects, transistors) that have a first minimum size, and the chiplet may include components (e.g., interconnects, transistors) that have a second minimum size, where the second minimum size is greater than the first minimum size. In some implementations, a first integrated device and a second integrated device of a package, may be fabricated using the same technology node or different technology nodes. In some implementations, a chiplet and another chiplet of a package, may be fabricated using the same technology node or different technology nodes.

A technology node may refer to a specific fabrication process and/or technology that is used to fabricate an integrated device and/or a chiplet. A technology node may specify the smallest possible size (e.g., minimum size) that can be fabricated (e.g., size of a transistor, width of trace, gap width between two transistors). Different technology nodes may have different yield loss. Different technology nodes may have different costs. Technology nodes that produce components (e.g., trace, transistors) with fine details are more expensive and may have higher yield loss, than a technology node that produces components (e.g., trace, transistors) with details that are less fine. Thus, more advanced technology nodes may be more expensive and may have higher yield loss, than less advanced technology nodes. When all of the functions of a package are implemented in single integrated devices, the same technology node is used to fabricate the entire integrated device, even if some of the functions of the integrated devices do not need to be fabricated using that particular technology node. Thus, the integrated device is locked into one technology node. To optimize the cost of a package, some of the functions can be implemented in different integrated devices and/or chiplets, where different integrated devices and/or chiplets may be fabricated using different technology nodes to reduce overall costs. For example, functions that require the use of the most advanced technology node may be implemented in an integrated device, and functions that can be implemented using a less advanced technology node can be implemented in another integrated device and/or one or more chiplets. One example, would be an integrated device, fabricated using a first technology node (e.g., most advanced technology node), that is configured to provide compute applications, and at least one chiplet, that is fabricated using a second technology node, that is configured to provide other functionalities, where the second technology node is not as costly as the first technology node, and where the second technology node fabricates components with minimum sizes that are greater than the minimum sizes of components fabricated using the first technology node. Examples of compute applications may include high performance computing and/or high performance processing, which may be achieved by fabricating and packing in as many transistors as possible in an integrated device, which is why an integrated device that is configured for compute applications may be fabricated using the most advanced technology node available, while other chiplets may be fabricated using less advanced technology nodes, since those chiplets may not require as many transistors to be fabricated in the chiplets. Thus, the combination of using different technology nodes (which may have different associated yield loss) for different integrated devices and/or chiplets, can reduce the overall cost of a package, compared to using a single integrated device to perform all the functions of the package.

Another advantage of splitting the functions into several integrated devices and/or chiplets, is that it allows improvements in the performance of the package without having to redesign every single integrated device and/or chiplet. For example, if a configuration of a package uses a first integrated device and a first chiplet, it may be possible to improve the performance of the package by changing the design of the first integrated device, while keeping the design of the first chiplet the same. Thus, the first chiplet could be reused with the improved and/or different configured first integrated device. This saves cost by not having to redesign the first chiplet, when packages with improved integrated devices are fabricated.

The package (e.g., 800, 900) may be implemented in a radio frequency (RF) package. The RF package may be a radio frequency front end (RFFE) package. A package (e.g., 800, 900) may be configured to provide Wireless Fidelity (WiFi) communication and/or cellular communication (e.g., 2G, 3G, 4G, 5G, 6G). The packages (e.g., 200, 600) may be configured to support Global System for Mobile (GSM) Communications, Universal Mobile Telecommunications System (UMTS), and/or Long-Term Evolution (LTE). The packages (e.g., 800, 900) may be configured to transmit and receive signals having different frequencies and/or communication protocols.

### Exemplary Sequence for Fabricating an Integrated Device

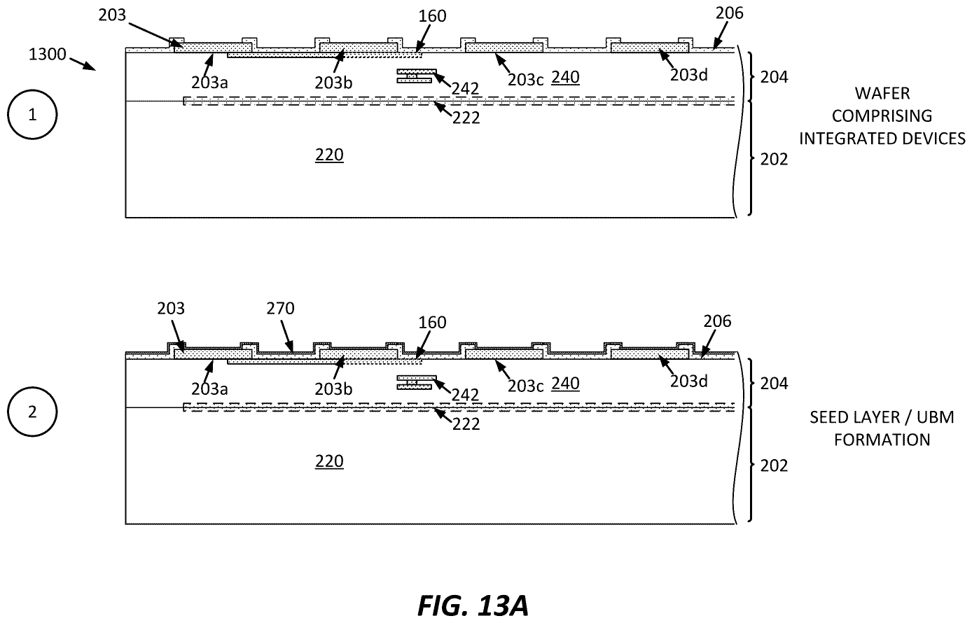

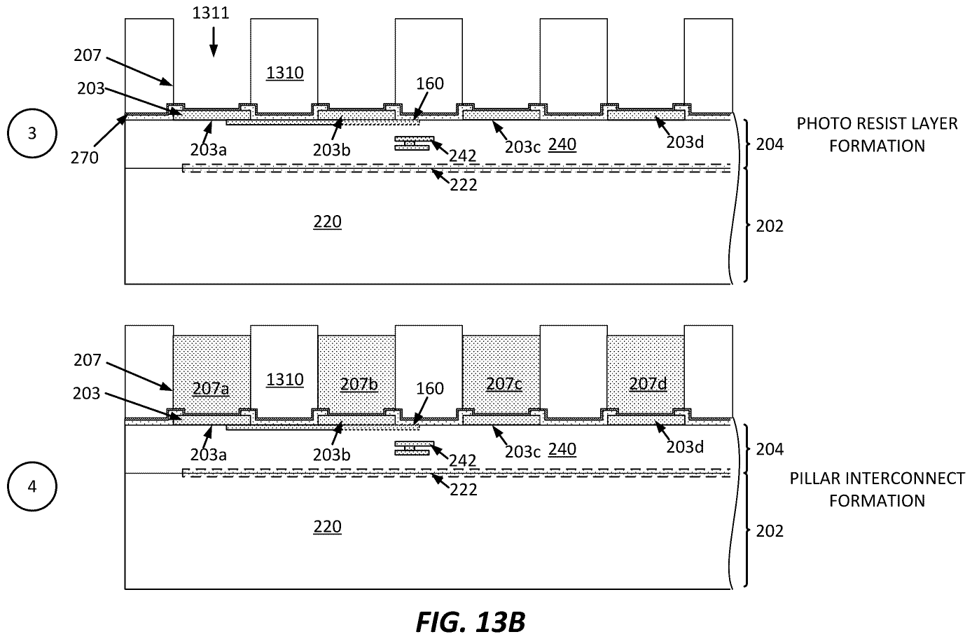

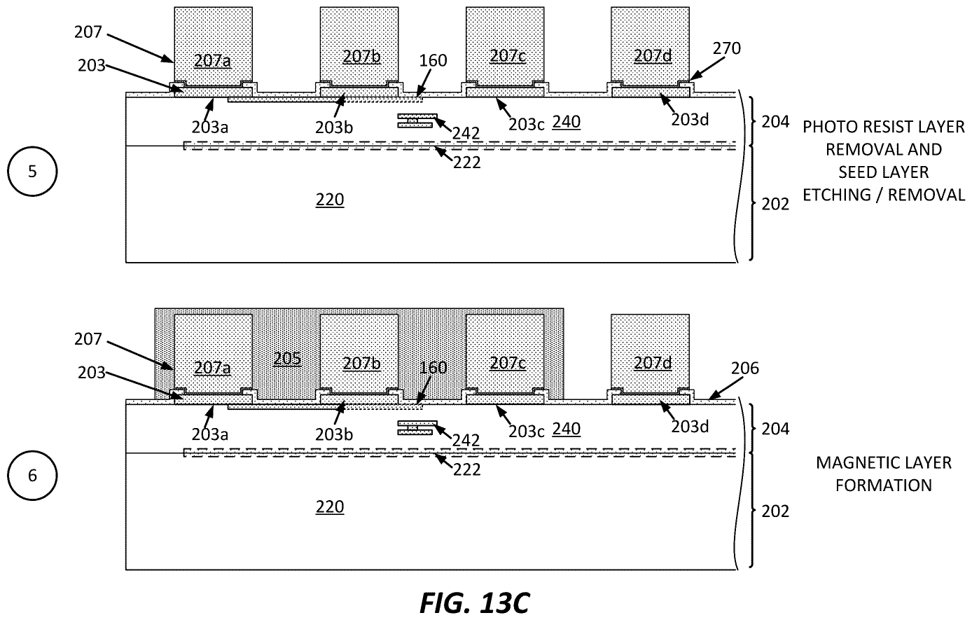

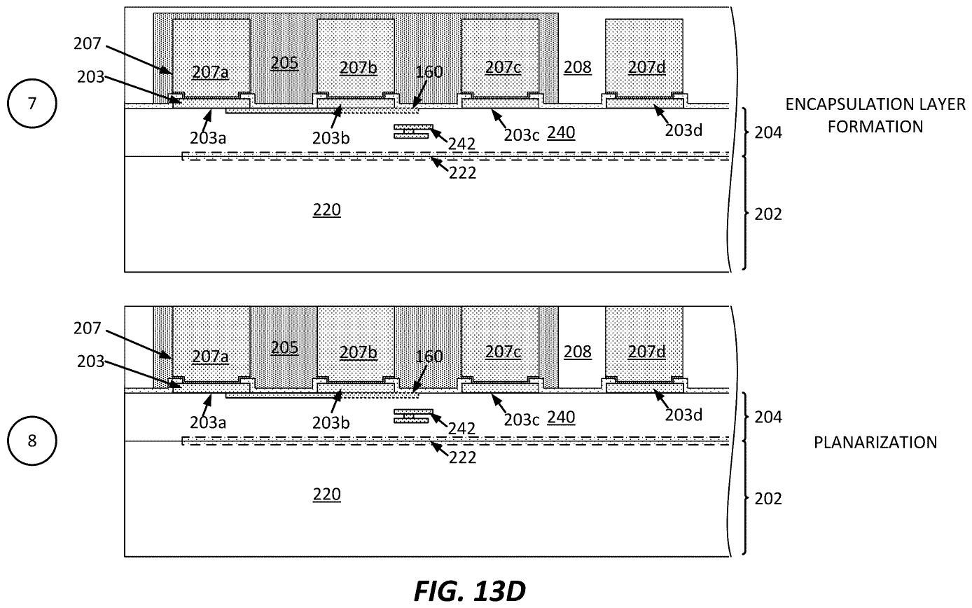

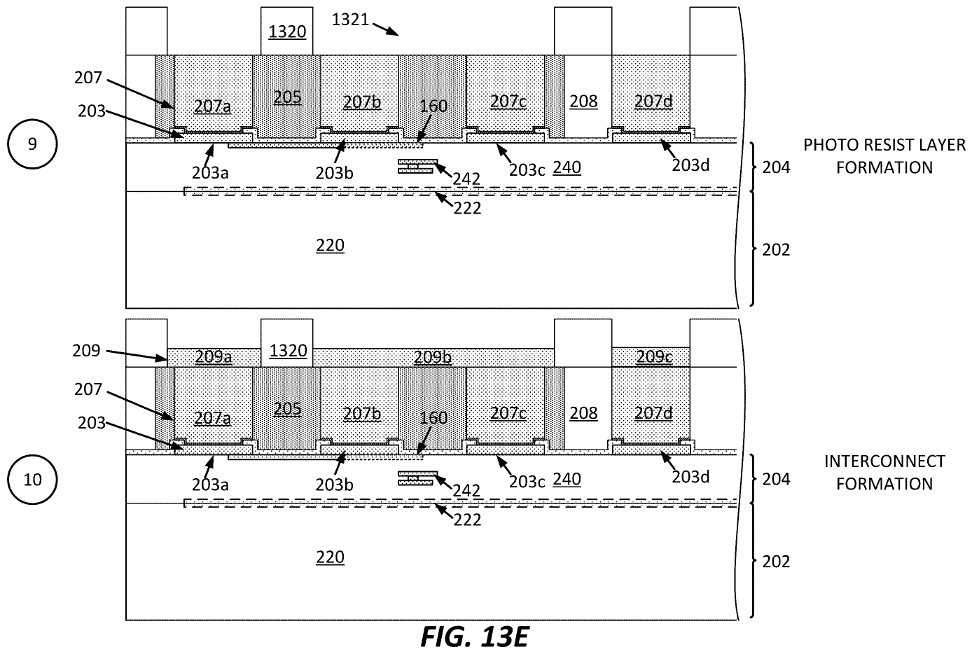

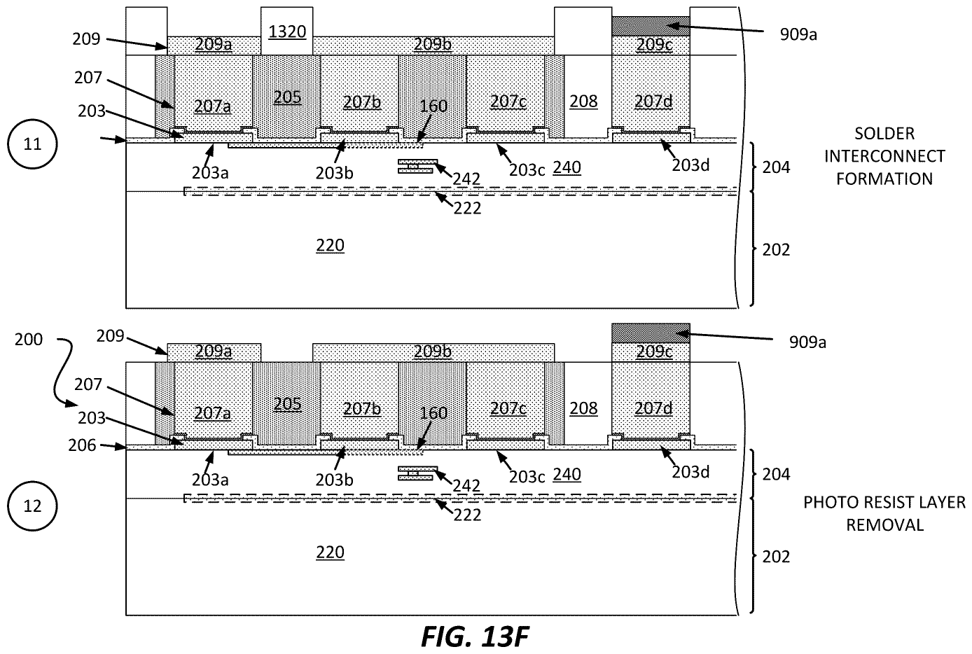

In some implementations, fabricating an integrated device includes several processes. FIGS. 13A-13F illustrate an exemplary sequence for providing or fabricating an integrated device comprising an inductor. In some implementations, the sequence of FIGS. 13A-13F may be used to provide or fabricate the integrated device 200. However, the process of FIGS. 13A-13F may be used to fabricate any integrated device described in the disclosure.

It should be noted that the sequence of FIGS. 13A-13F may combine one or more stages in order to simplify and/or clarify the sequence for providing or fabricating an integrated device. In some implementations, the order of the processes may be changed or modified. In some implementations, one or more of processes may be replaced or substituted without departing from the scope of the disclosure.

Stage 1, as shown in FIG. 13A, illustrates a state after a wafer 1300 is provided. The wafer 1300 may include a die substrate portion 202, a die interconnection portion 204, an inductor 160, a plurality of pad interconnects 203, a passivation layer 206, as described above in at least FIG. 2.

Stage 2 illustrates a state after a seed layer is formed over the wafer 1300. The seed layer 270 may be an under bump metallization interconnect. The seed layer 270 may be formed over the passivation layer 206 and the plurality of pad interconnects 203. The seed layer may include copper (Cu). A sputtering process may be used to form the seed layer 270.

Stage 3, as shown in FIG. 13B, illustrates a state after a photo resist layer 1310 is formed over the wafer 1300. For example, the photo resist layer 1310 may be formed over the seed layer 270 (e.g., over the under bump metallization interconnect). The photo resist layer 1310 may be patterned to include a plurality of openings 1311 in the photo resist layer 1310. The photo resist layer 1310 may be coated over the wafer 1300. A photolithography process may be used to form and define the pattern of the photo resist layer 1310. For example, an exposure process and development process may be used to form the plurality of openings 1311 in the photo resist layer 1310. The plurality of openings 1311 may be located over the plurality of pad interconnects 203.

Stage 4 illustrates a state after the plurality of pillar interconnects 207 are formed and coupled to the seed layer 270. A plating process may be used to form the plurality of pillar interconnects 207. The plurality of pillar interconnects 207 may be formed in the plurality of openings 1311 of the photo resist layer 1310. The pillar interconnect 207a may be coupled to the pad interconnect 203a, through the seed layer 270. The pillar interconnect 207b may be coupled to the pad interconnect 203b, through the seed layer 270. The pillar interconnect 207c may be coupled to the pad interconnect 203c, through the seed layer 270. The pillar interconnect 207d may be coupled to the pad interconnect 203d, through the seed layer 270.

Stage 5, as shown in FIG. 13C, illustrates a state after the photo resist layer 1310 is removed. Stage 5 also illustrates a state after portions of the seed layer 270 are removed. An etching process may be used to remove portions of the seed layer 270. The portions of the seed layer 270 that are removed are portions that are not covered by the plurality of pillar interconnects 207.

Stage 6 illustrates a state after a magnetic layer 205 is formed over the passivation layer 206 and some of the pillar interconnects from the plurality of pillar interconnects 207. A stencil print process and/or jetting process may be used to provide and form the magnetic layer 205. The magnetic layer 205 may at least partially surround some of the pillar interconnects from the plurality of pillar interconnects.

Stage 7, as shown in FIG. 13D, illustrates a state after an encapsulation layer 208 is provided and coupled to the passivation layer 206. The encapsulation layer 208 may include a mold, a resin, an epoxy and/or a filler. The encapsulation layer 208 may at least partially encapsulate the plurality of pillar interconnects 207 and the magnetic layer 205. The encapsulation layer 208 may be provided by using a compression and transfer molding process, a sheet molding process, or a liquid molding process.

Stage 8 illustrates a state after portions of the encapsulation layer 208 are removed. A planarization process may be performed on the encapsulation layer 208. A grinding process may be used to remove portions of the encapsulation layer 208. The planarization process may also remove portions of the plurality of pillar interconnects 207 and/or portions of the magnetic layer 205.

Stage 9, as shown in FIG. 13E, illustrates a state after a photo resist layer 1320 is formed over the encapsulation layer 208. For example, the photo resist layer 1320 may be formed over the magnetic layer 205 and/or the encapsulation layer 208. The photo resist layer 1320 may be patterned to include a plurality of openings 1321 in the photo resist layer 1320. The photo resist layer 1320 may be coated over the magnetic layer 205 and the encapsulation layer 208. A photolithography process may be used to form and define the pattern of the photo resist layer 1320. For example, an exposure process and development process may be used to form the plurality of openings 1321 in the photo resist layer 1320. The plurality of openings 1321 may be located over the plurality of pillar interconnects 207.

Stage 10 illustrates a state after the plurality of interconnects 209 are formed and coupled to the plurality of pillar interconnects 207. A plating process may be used to form the plurality of interconnects 209. The plurality of interconnects 209 may be formed in the plurality of openings 1321 of the photo resist layer 1320. The interconnect 209a may be coupled to the pillar interconnect 207a. The interconnect 209b may be coupled to the pillar interconnect 207b and the pillar interconnect 207c. The interconnect 209c may be coupled to the pillar interconnect 207d.

Stage 11, as shown in FIG. 13F illustrates a state after solder interconnect 909a is formed and coupled to the interconnect 209c. A pasting process may be used to form the solder interconnect 909a in an opening of the photo resist layer 1320.

Stage 12 illustrates a state after the photo resist layer 1320 is removed. In some implementation a singulation process may be performed on the wafer 1300 to form several integrated devices with inductors. Stage 12 may illustrate an example of the integrated device 200.

### Exemplary Sequence for Fabricating an Integrated Device

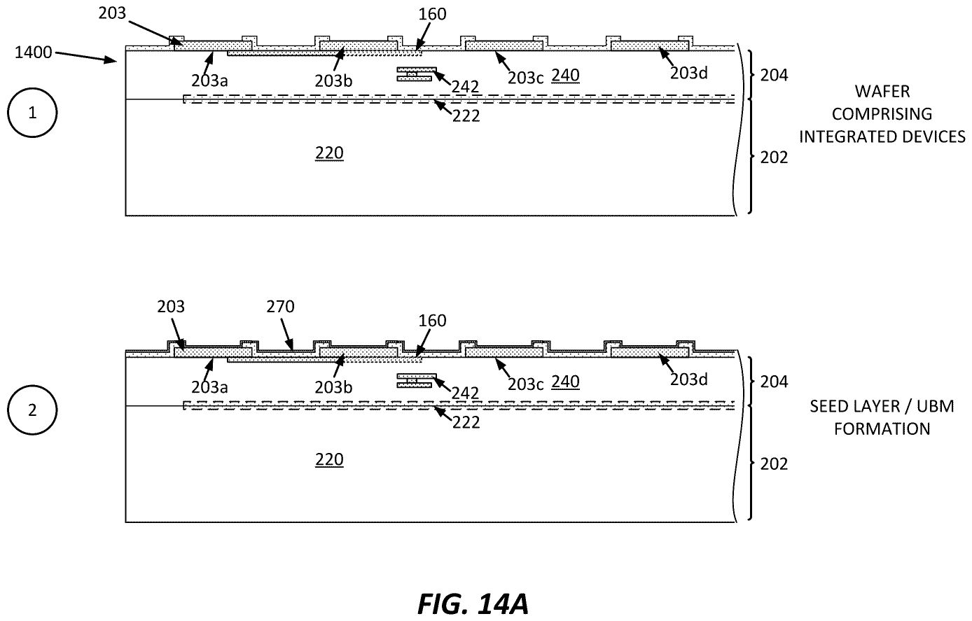

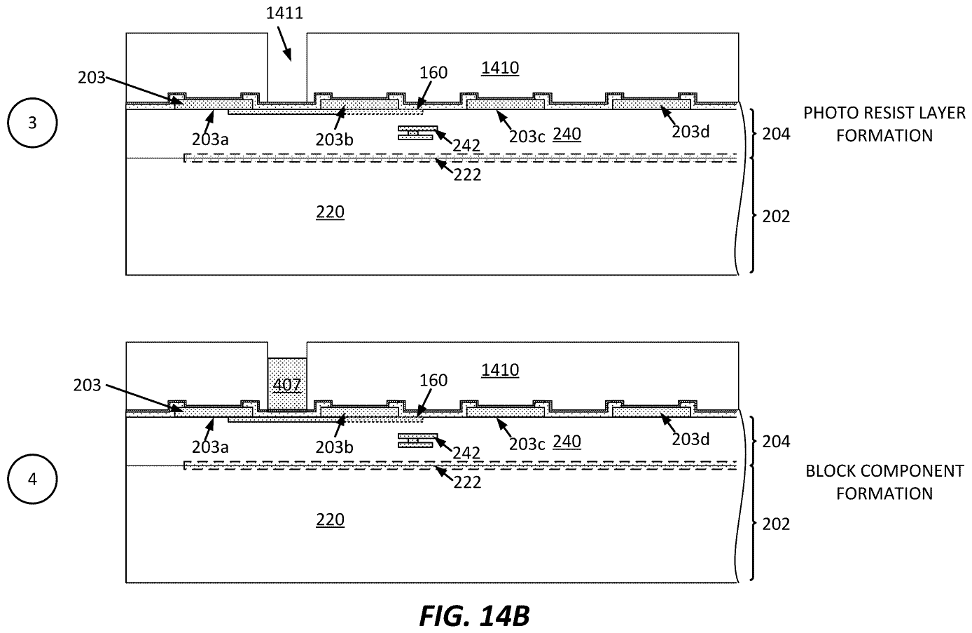

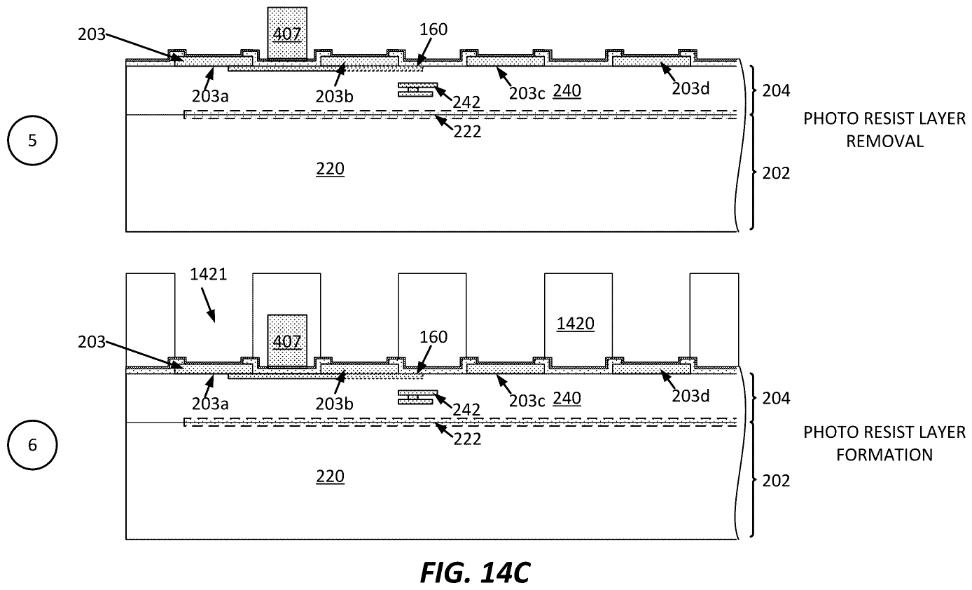

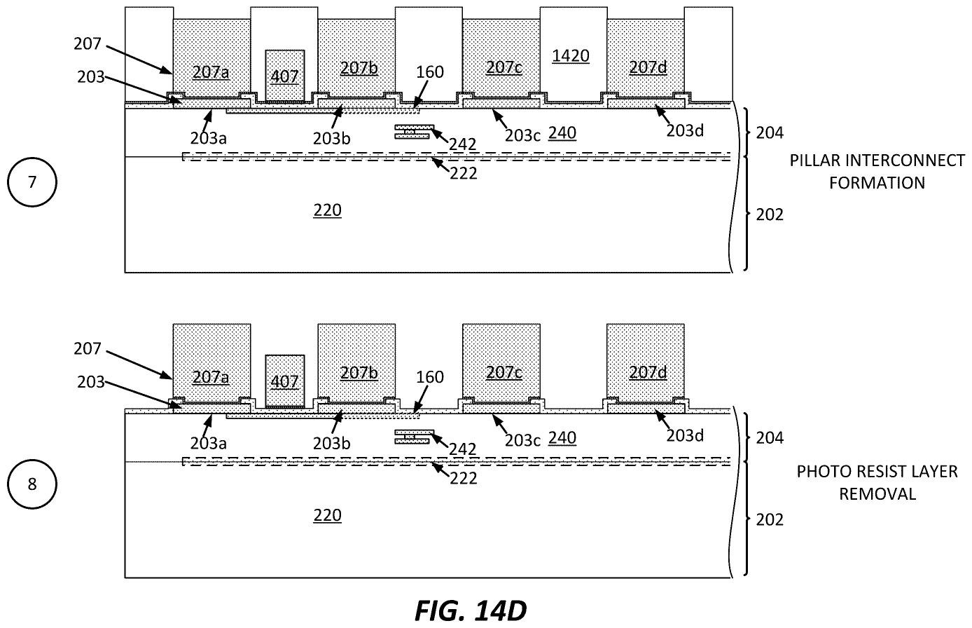

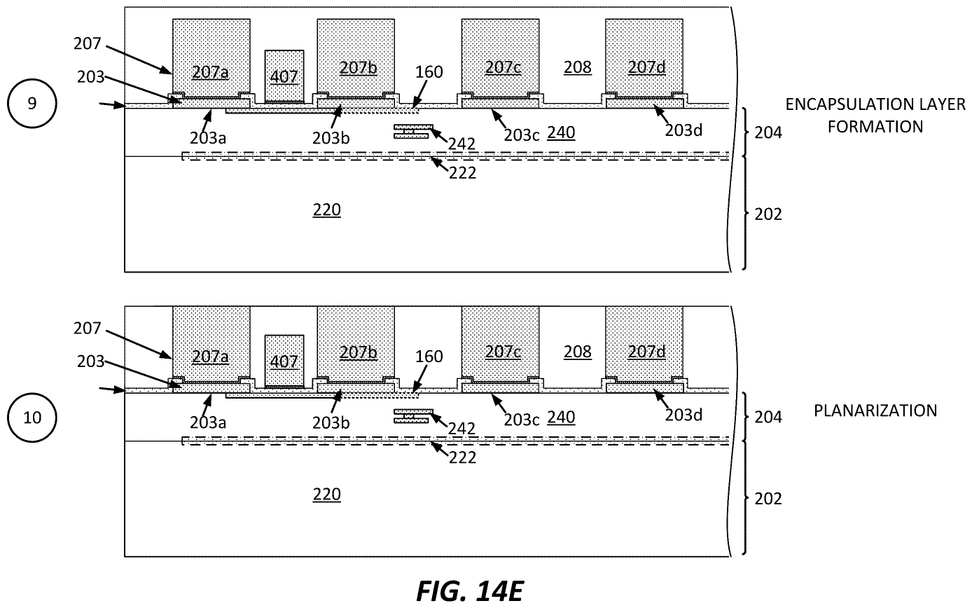

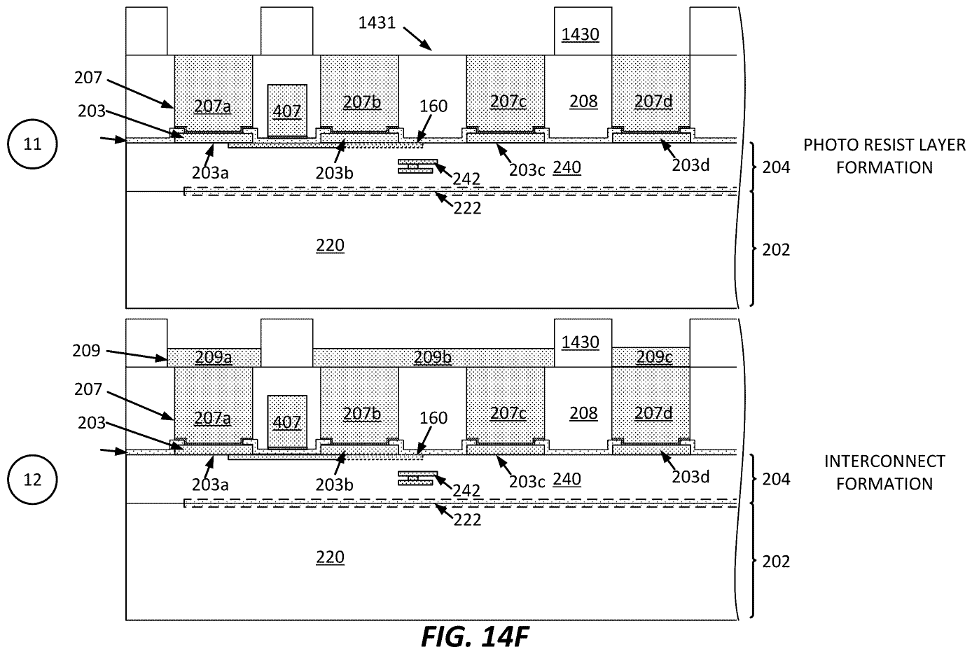

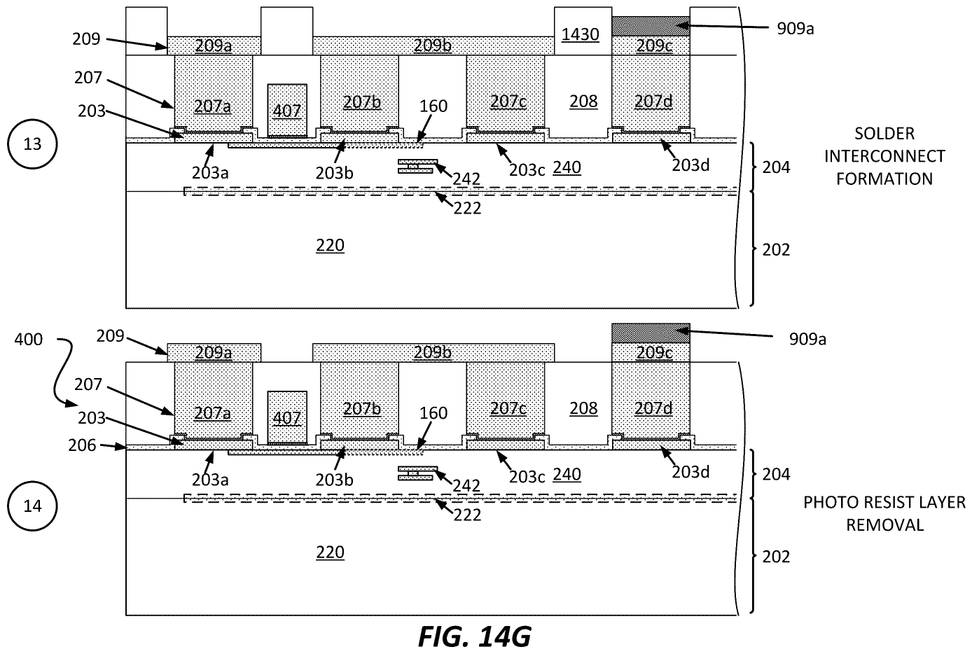

In some implementations, fabricating an integrated device includes several processes. FIGS. 14A-14G illustrate an exemplary sequence for providing or fabricating an integrated device comprising an inductor. In some implementations, the sequence of FIGS. 14A-14G may be used to provide or fabricate the integrated device 400. However, the process of FIGS. 14A-14G may be used to fabricate any integrated device described in the disclosure.

It should be noted that the sequence of FIGS. 14A-14G may combine one or more stages in order to simplify and/or clarify the sequence for providing or fabricating an integrated device. In some implementations, the order of the processes may be changed or modified. In some implementations, one or more of processes may be replaced or substituted without departing from the scope of the disclosure.

Stage 1, as shown in FIG. 14A, illustrates a state after a wafer 1400 is provided. The wafer 1400 may include a die substrate portion 202, a die interconnection portion 204, an inductor 160, a plurality of pad interconnects 203, a passivation layer 206, as described above in at least FIG. 4.

Stage 2 illustrates a state after a seed layer is formed over the wafer 1400. The seed layer 270 may be an under bump metallization interconnect. The seed layer 270 may be formed over the passivation layer 206 and the plurality of pad interconnects 203. The seed layer may include copper (Cu). A sputtering process may be used to form the seed layer 270.

Stage 3, as shown in FIG. 14B, illustrates a state after a photo resist layer 1410 is formed over the wafer 1400. For example, the photo resist layer 1410 may be formed over the seed layer 270 (e.g., over the under bump metallization interconnect). The photo resist layer 1410 may be patterned to include a plurality of openings 1411 in the photo resist layer 1410. The photo resist layer 1410 may be coated over the wafer 1400. A photolithography process may be used to form and define the pattern of the photo resist layer 1410. For example, an exposure process and development process may be used to form the plurality of openings 1411 in the photo resist layer 1410.

Stage 4 illustrates a state after a block component 407 is formed and coupled to the seed layer 270. A plating process may be used to form the block component 407. The block component 407 may include nickel (Ni). The block component 407 may include a magnetic material. The block component 407 may be coupled to the seed layer 270. The seed layer 270 may be considered part of the block component 407. In some implementations, the block component 407 may be a magnetic dummy component. For example, the block component 407 is not electrically touching other electrical components.

Stage 5, as shown in FIG. 14C, illustrates a state after the photo resist layer 1410 is removed.

Stage 6 illustrates a state after a photo resist layer 1420 is formed over the wafer 1400. For example, the photo resist layer 1420 may be formed over the seed layer 270 (e.g., over the under bump metallization interconnect). The photo resist layer 1420 may be patterned to include a plurality of openings 1421 in the photo resist layer 1420. The photo resist layer 1420 may be coated over the wafer 1400. A photolithography process may be used to form and define the pattern of the photo resist layer 1420. For example, an exposure process and development process may be used to form the plurality of openings 1421 in the photo resist layer 1420. The plurality of openings 1421 may be located over the plurality of pad interconnects 203.

Stage 7, as shown in FIG. 14D illustrates a state after the plurality of pillar interconnects 207 are formed and coupled to the seed layer 270. A plating process may be used to form the plurality of pillar interconnects 207. The plurality of pillar interconnects 207 may be formed in the plurality of openings 1421 of the photo resist layer 1420. The pillar interconnect 207a may be coupled to the pad interconnect 203a, through the seed layer 270. The pillar interconnect 207b may be coupled to the pad interconnect 203b, through the seed layer 270. The pillar interconnect 207c may be coupled to the pad interconnect 203c, through the seed layer 270. The pillar interconnect 207d may be coupled to the pad interconnect 203d, through the seed layer 270.

Stage 8 illustrates a state after the photo resist layer 1420 is removed. Stage 8 also illustrates a state after portions of the seed layer 270 are removed. An etching process may be used to remove portions of the seed layer 270. The portions of the seed layer 270 that are removed are portions that are not covered by the plurality of pillar interconnects 207.

Stage 9, as shown in FIG. 14E, illustrates a state after an encapsulation layer 208 is provided and coupled to the passivation layer 206. The encapsulation layer 208 may at least partially encapsulate the plurality of pillar interconnects 207. The encapsulation layer 208 may include a mold, a resin, an epoxy and/or a filler. The encapsulation layer 208 may be provided by using a compression and transfer molding process, a sheet molding process, or a liquid molding process.

Stage 10 illustrates a state after portions of the encapsulation layer 208 are removed. A planarization process may be performed on the encapsulation layer 208. A grinding process may be used to remove portions of the encapsulation layer 208. The planarization process may also remove portions of the plurality of pillar interconnects 207.

Stage 11, as shown in FIG. 14F, illustrates a state after a photo resist layer 1430 is formed over the encapsulation layer 208. The photo resist layer 1430 may be patterned to include a plurality of openings 1431 in the photo resist layer 1430. The photo resist layer 1430 may be coated over the encapsulation layer 208. A photolithography process may be used to form and define the pattern of the photo resist layer 1430. For example, an exposure process and development process may be used to form the plurality of openings 1431 in the photo resist layer 1430. The plurality of openings 1431 may be located over the plurality of pillar interconnects 207.

Stage 12 illustrates a state after the plurality of interconnects 209 are formed and coupled to the plurality of pillar interconnects 207. A plating process may be used to form the plurality of interconnects 209. The plurality of interconnects 209 may be formed in the plurality of openings 1431 of the photo resist layer 1430. The interconnect 209a may be coupled to the pillar interconnect 207a. The interconnect 209b may be coupled to the pillar interconnect 207b and the pillar interconnect 207c. The interconnect 209c may be coupled to the pillar interconnect 207d.

Stage 13, as shown in FIG. 14G illustrates a state after solder interconnect 909a is formed and coupled to the interconnect 209c. A pasting process may be used to form the solder interconnect 909a in an opening of the photo resist layer 1430.

Stage 14 illustrates a state after the photo resist layer 1430 is removed. In some implementation a singulation process may be performed on the wafer 1400 to form several integrated devices with inductors. Stage 14 may illustrate an example of the integrated device 400.

### Exemplary Flow Diagram of a Method for Fabricating an Integrated Device

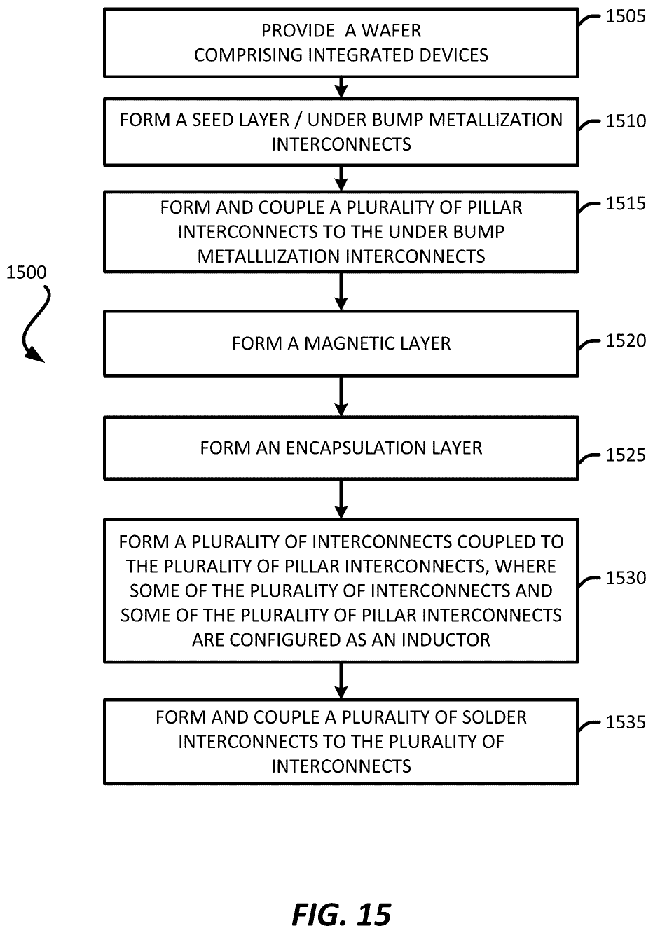

In some implementations, fabricating an integrated device includes several processes. FIG. 15 illustrates an exemplary flow diagram of a method 1500 for providing or fabricating an integrated device. In some implementations, the method 1500 of FIG. 15 may be used to provide or fabricate the integrated device 200 of FIG. 2. However, the method 1500 may be used to provide or fabricate any other integrated devices.

It should be noted that the method 1500 of FIG. 15 may combine one or more processes in order to simplify and/or clarify the method for providing or fabricating an integrated device. In some implementations, the order of the processes may be changed or modified.

The method provides (at 1505) a wafer comprising integrated devices. Stage 1 of FIG. 13A, illustrates and describes an example of a state after a wafer 1300 is provided. The wafer 1300 may include a die substrate portion 202, a die interconnection portion 204, an inductor 160, a plurality of pad interconnects 203, a passivation layer 206, as described above in at least FIG. 2.

The method forms (at 1510) a seed layer. Stage 2 of FIG. 13A, illustrates and describes an example of a state after a seed layer is formed over the wafer 1300. The seed layer 270 may be an under bump metallization interconnect. The seed layer 270 may be formed over the passivation layer 206 and the plurality of pad interconnects 203. The seed layer may include copper (Cu). A sputtering process may be used to form the seed layer 270.

The method forms (at 1515) forms a plurality of pillar interconnects that are coupled to the seed layer and/or the plurality of pad interconnects. Stage 3 of FIG. 13B through stage 5 of FIG. 13C illustrates an example of forming a plurality of pillar interconnects.

Stage 3 of FIG. 13B, illustrates and describes an example of a state after a photo resist layer 1310 is formed over the wafer 1300. For example, the photo resist layer 1310 may be formed over the seed layer 270 (e.g., over the under bump metallization interconnect). The photo resist layer 1310 may be patterned to include a plurality of openings 1311 in the photo resist layer 1310. The photo resist layer 1310 may be coated over the wafer 1300. A photolithography process may be used to form and define the pattern of the photo resist layer 1310. For example, an exposure process and development process may be used to form the plurality of openings 1311 in the photo resist layer 1310. The plurality of openings 1311 may be located over the plurality of pad interconnects 203.

Stage 4 of FIG. 13B, illustrates and describes an example of a state after the plurality of pillar interconnects 207 are formed and coupled to the seed layer 270. A plating process may be used to form the plurality of pillar interconnects 207. The plurality of pillar interconnects 207 may be formed in the plurality of openings 1311 of the photo resist layer 1310. The pillar interconnect 207a may be coupled to the pad interconnect 203a, through the seed layer 270. The pillar interconnect 207b may be coupled to the pad interconnect 203b, through the seed layer 270. The pillar interconnect 207c may be coupled to the pad interconnect 203c, through the seed layer 270. The pillar interconnect 207d may be coupled to the pad interconnect 203d, through the seed layer 270.

Stage 5 of FIG. 13C, illustrates and describes an example of a state after the photo resist layer 1310 is removed. Stage 5 also illustrates a state after portions of the seed layer 270 are removed. An etching process may be used to remove portions of the seed layer 270. The portions of the seed layer 270 that are removed are portions that are not covered by the plurality of pillar interconnects 207.

The method forms (at 1520) a magnetic layer. Stage 6 of FIG. 13C, illustrates and describes an example of a state after a magnetic layer 205 is formed over the passivation layer 206 and some of the pillar interconnects from the plurality of pillar interconnects 207. A stencil print process and/or jetting process may be used to provide and form the magnetic layer 205. The magnetic layer 205 may at least partially surround some of the pillar interconnects from the plurality of pillar interconnects.

The method forms (at 1525) an encapsulation layer. Stage 7 of FIG. 13D, illustrates and describes an example of a state after an encapsulation layer 208 is provided and coupled to the passivation layer 206. The encapsulation layer 208 may include a mold, a resin, an epoxy and/or a filler. The encapsulation layer 208 may at least partially encapsulate the plurality of pillar interconnects 207 and the magnetic layer 205. The encapsulation layer 208 may be provided by using a compression and transfer molding process, a sheet molding process, or a liquid molding process.

In some implementations, forming the encapsulation layer may include planarizing the encapsulation layer. Stage 8 of FIG. 13D, illustrates and describes an example of a state after portions of the encapsulation layer 208 are removed. A planarization process may be performed on the encapsulation layer 208. A grinding process may be used to remove portions of the encapsulation layer 208. The planarization process may also remove portions of the plurality of pillar interconnects 207 and/or portions of the magnetic layer 205.

The method forms (at 1530) a plurality of interconnects that are coupled to the plurality of pillar interconnects. Stage 9 of FIG. 13E through stage 10 of FIG. 13E illustrates an example of forming a plurality of interconnects.

Stage 9 of FIG. 13E, illustrates and describes an example of a state after a photo resist layer 1320 is formed over the encapsulation layer 208. For example, the photo resist layer 1320 may be formed over the magnetic layer 205 and/or the encapsulation layer 208. The photo resist layer 1320 may be patterned to include a plurality of openings 1321 in the photo resist layer 1320. The photo resist layer 1320 may be coated over the magnetic layer 205 and the encapsulation layer 208. A photolithography process may be used to form and define the pattern of the photo resist layer 1320. For example, an exposure process and development process may be used to form the plurality of openings 1321 in the photo resist layer 1320. The plurality of openings 1321 may be located over the plurality of pillar interconnects 207.

Stage 10 of FIG. 13E, illustrates and describes an example of a state after the plurality of interconnects 209 are formed and coupled to the plurality of pillar interconnects 207. A plating process may be used to form the plurality of interconnects 209. The plurality of interconnects 209 may be formed in the plurality of openings 1321 of the photo resist layer 1320. The interconnect 209a may be coupled to the pillar interconnect 207a. The interconnect 209b may be coupled to the pillar interconnect 207b and the pillar interconnect 207c. The interconnect 209c may be coupled to the pillar interconnect 207d.

The method forms and couples (at 1535) to the plurality of interconnects. Stage 11 of FIG. 13F, illustrates and describes an example of a state after solder interconnect 909a is formed and coupled to the interconnect 209c. A pasting process may be used to form the solder interconnect 909a in an opening of the photo resist layer 1320.

The method may remove a photo resist layer. Stage 12 of FIG. 13F, illustrates and describes an example of a state after the photo resist layer 1320 is removed. In some implementation a singulation process may be performed on the wafer 1300 to form several integrated devices with inductors. Stage 12 may illustrate an example of the integrated device 200.

### Exemplary Flow Diagram of a Method for Fabricating an Integrated Device

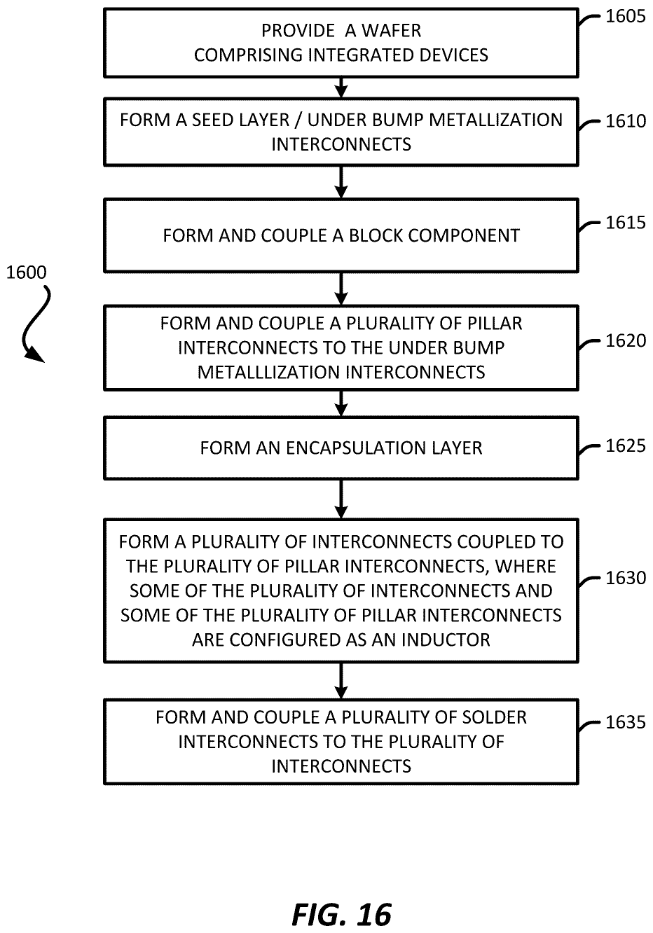

In some implementations, fabricating an integrated device includes several processes. FIG. 16 illustrates an exemplary flow diagram of a method 1600 for providing or fabricating an integrated device. In some implementations, the method 1600 of FIG. 16 may be used to provide or fabricate the integrated device 400 of FIG. 4. However, the method 1600 may be used to provide or fabricate any other integrated devices.

It should be noted that the method 1600 of FIG. 16 may combine one or more processes in order to simplify and/or clarify the method for providing or fabricating an integrated device. In some implementations, the order of the processes may be changed or modified.

The method provides (at 1605) a wafer comprising integrated devices. Stage 1 of FIG. 14A, illustrates and describes an example of a state after a wafer 1400 is provided. The wafer 1400 may include a die substrate portion 202, a die interconnection portion 204, an inductor 160, a plurality of pad interconnects 203, a passivation layer 206, as described above in at least FIG. 4.

The method forms (at 1610) a seed layer. Stage 2 of FIG. 14A, illustrates and describes an example of a state after a seed layer is formed over the wafer 1400. The seed layer 270 may be an under bump metallization interconnect. The seed layer 270 may be formed over the passivation layer 206 and the plurality of pad interconnects 203. The seed layer may include copper (Cu). A sputtering process may be used to form the seed layer 270.

The method forms and couples (at 615) a block component to the seed layer. Stage 3 of FIG. 14B through stage 5 of FIG. 14C, illustrates and describes an example of forming a block component.

Stage 3 of FIG. 14B, illustrates and describes an example of a state after a photo resist layer 1410 is formed over the wafer 1400. For example, the photo resist layer 1410 may be formed over the seed layer 270 (e.g., over the under bump metallization interconnect). The photo resist layer 1410 may be patterned to include a plurality of openings 1411 in the photo resist layer 1410. The photo resist layer 1410 may be coated over the wafer 1400. A photolithography process may be used to form and define the pattern of the photo resist layer 1410. For example, an exposure process and development process may be used to form the plurality of openings 1411 in the photo resist layer 1410.

Stage 4 of FIG. 14B, illustrates and describes an example of a state after a block component 407 is formed and coupled to the seed layer 270. A plating process may be used to form the block component 407. The block component 407 may include the seed layer 270. Stage 5, as shown in FIG. 14C, illustrates a state after the photo resist layer 1410 is removed.

The method forms (at 1515) forms a plurality of pillar interconnects that are coupled to the seed layer and/or the plurality of pad interconnects. Stage 6 of FIG. 14C through stage 8 of FIG. 14D, illustrate and describe an example of forming a plurality of pillar interconnects.

Stage 6 of FIG. 14C, illustrates and describes an example of a state after a photo resist layer 1420 is formed over the wafer 1400. For example, the photo resist layer 1420 may be formed over the seed layer 270 (e.g., over the under bump metallization interconnect). The photo resist layer 1420 may be patterned to include a plurality of openings 1421 in the photo resist layer 1420. The photo resist layer 1420 may be coated over the wafer 1400. A photolithography process may be used to form and define the pattern of the photo resist layer 1420. For example, an exposure process and development process may be used to form the plurality of openings 1421 in the photo resist layer 1420. The plurality of openings 1421 may be located over the plurality of pad interconnects 203.

Stage 7 of FIG. 14D, illustrates and describes an example of a state after the plurality of pillar interconnects 207 are formed and coupled to the seed layer 270. A plating process may be used to form the plurality of pillar interconnects 207. The plurality of pillar interconnects 207 may be formed in the plurality of openings 1421 of the photo resist layer 1420. The pillar interconnect 207a may be coupled to the pad interconnect 203a, through the seed layer 270. The pillar interconnect 207b may be coupled to the pad interconnect 203b, through the seed layer 270. The pillar interconnect 207c may be coupled to the pad interconnect 203c, through the seed layer 270. The pillar interconnect 207d may be coupled to the pad interconnect 203d, through the seed layer 270.

Stage 8 of FIG. 14D, illustrates and describes an example of a state after the photo resist layer 1420 is removed. Stage 8 also illustrates a state after portions of the seed layer 270 are removed. An etching process may be used to remove portions of the seed layer 270. The portions of the seed layer 270 that are removed are portions that are not covered by the plurality of pillar interconnects 207.

The method forms (at 1625) an encapsulation layer. Stage 9 FIG. 14E, illustrates and describes an example of a state after an encapsulation layer 208 is provided and coupled to the passivation layer 206. The encapsulation layer 208 may at least partially encapsulate the plurality of pillar interconnects 207. The encapsulation layer 208 may include a mold, a resin, an epoxy and/or a filler. The encapsulation layer 208 may be provided by using a compression and transfer molding process, a sheet molding process, or a liquid molding process. In some implementations, forming an encapsulation layer may include planarizing the encapsulation layer.

Stage 10 of FIG. 14E, illustrates and describes an example of a state after portions of the encapsulation layer 208 are removed. A planarization process may be performed on the encapsulation layer 208. A grinding process may be used to remove portions of the encapsulation layer 208. The planarization process may also remove portions of the plurality of pillar interconnects 207.

The method forms (at 1630) a plurality of interconnects that are coupled to the plurality of pillar interconnects. Stage 11 of FIG. 14F through stage 12 of FIG. 14F illustrate and describe an example of forming a plurality of interconnects.

Stage 11 of FIG. 14F, illustrates and describes an example of a state after a photo resist layer 1430 is formed over the encapsulation layer 208. The photo resist layer 1430 may be patterned to include a plurality of openings 1431 in the photo resist layer 1430. The photo resist layer 1430 may be coated over the encapsulation layer 208. A photolithography process may be used to form and define the pattern of the photo resist layer 1430. For example, an exposure process and development process may be used to form the plurality of openings 1431 in the photo resist layer 1430. The plurality of openings 1431 may be located over the plurality of pillar interconnects 207.

Stage 12 of FIG. 14F, illustrates and describes an example of a state after the plurality of interconnects 209 are formed and coupled to the plurality of pillar interconnects 207. A plating process may be used to form the plurality of interconnects 209. The plurality of interconnects 209 may be formed in the plurality of openings 1431 of the photo resist layer 1430. The interconnect 209a may be coupled to the pillar interconnect 207a. The interconnect 209b may be coupled to the pillar interconnect 207b and the pillar interconnect 207c. The interconnect 209c may be coupled to the pillar interconnect 207d.

The method forms and couples (at 1635) a plurality of solder interconnects to the plurality of interconnects. Stage 13 of FIG. 14G, illustrates and describes an example of a state after solder interconnect 909a is formed and coupled to the interconnect 209c. A pasting process may be used to form the solder interconnect 909a in an opening of the photo resist layer 1430.

The method may remove a photo resist layer. Stage 14 of FIG. 14G, illustrates and describes an example of a state after the photo resist layer 1430 is removed. In some implementation a singulation process may be performed on the wafer 1400 to form several integrated devices with inductors. Stage 14 may illustrate an example of the integrated device 400.

### Exemplary Electronic Devices

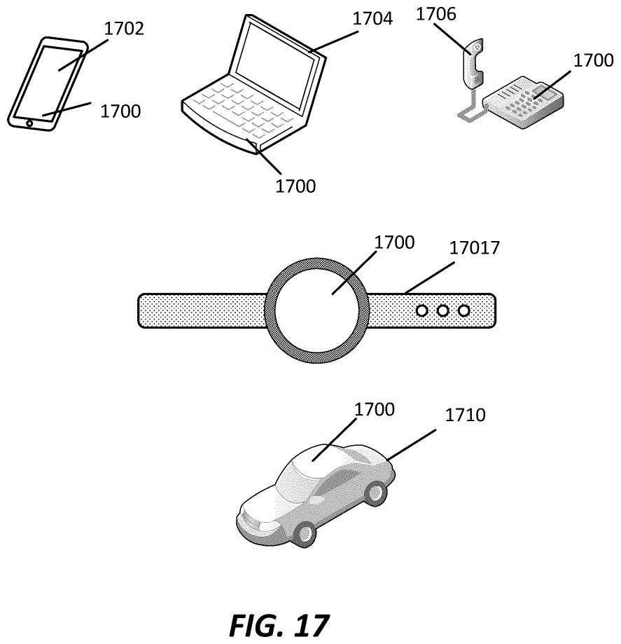

FIG. 17 illustrates various electronic devices that may be integrated with any of the aforementioned device, integrated device, integrated circuit (IC) package, integrated circuit (IC) device, semiconductor device, integrated circuit, die, interposer, package, package-on-package (PoP), System in Package (SiP), or System on Chip (SoC). For example, a mobile phone device 1702, a laptop computer device 1704, a fixed location terminal device 1706, a wearable device 1708, or automotive vehicle 1710 may include a device 1700 as described herein. The device 1700 may be, for example, any of the devices and/or integrated circuit (IC) packages described herein. The devices 1702, 1704, 1706 and 1708 and the vehicle 1710 illustrated in FIG. 17 are merely exemplary. Other electronic devices may also feature the device 1700 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 1-12, 13A-13F, 14A-14G, and 15-17 may be rearranged and/or combined into a single component, process, feature or function or embodied in several components, processes, or functions. Additional elements, components, processes, and/or functions may also be added without departing from the disclosure. It should also be noted FIGS. 1-12, 13A-13F, 14A-14G, and 15-17 and its corresponding description in the present disclosure is not limited to dies and/or ICs. In some implementations, FIGS. 1-12, 13A-13F, 14A-14G, and 15-17 and its corresponding description may be used to manufacture, create, provide, and/or produce devices and/or integrated devices. In some implementations, a device may include a die, an integrated device, an integrated passive device (IPD), a die package, an integrated circuit (IC) device, a device package, an integrated circuit (IC) package, a wafer, a semiconductor device, a package-on-package (PoP) device, a heat dissipating device and/or an interposer.

It is noted that the figures in the disclosure may represent actual representations and/or conceptual representations of various parts, components, objects, devices, packages, integrated devices, integrated circuits, and/or transistors. In some instances, the figures may not be to scale. In some instances, for purpose of clarity, not all components and/or parts may be shown. In some instances, the position, the location, the sizes, and/or the shapes of various parts and/or components in the figures may be exemplary. In some implementations, various components and/or parts in the figures may be optional.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling (e.g., mechanical coupling) between two objects. For example, if object A physically touches object B, and object B touches object C, then objects A and C may still be considered coupled to one another—even if they do not directly physically touch each other. An object A, that is coupled to an object B, may be coupled to at least part of object B. The term “electrically coupled” may mean that two objects are directly or indirectly coupled together such that an electrical current (e.g., signal, power, ground) may travel between the two objects. Two objects that are electrically coupled may or may not have an electrical current traveling between the two objects. The use of the terms “first”, “second”, “third” and “fourth” (and/or anything above fourth) is arbitrary. Any of the components described may be the first component, the second component, the third component or the fourth component. For example, a component that is referred to a second component, may be the first component, the second component, the third component or the fourth component. The terms “encapsulate”, “encapsulating” and/or any derivation means that the object may partially encapsulate or completely encapsulate another object. The terms “top” and “bottom” are arbitrary. A component that is located on top may be located over a component that is located on a bottom. A top component may be considered a bottom component, and vice versa. As described in the disclosure, a first component that is located “over” a second component may mean that the first component is located above or below the second component, depending on how a bottom or top is arbitrarily defined. In another example, a first component may be located over (e.g., above) a first surface of the second component, and a third component may be located over (e.g., below) a second surface of the second component, where the second surface is opposite to the first surface. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component. A first component that is located “in” a second component may be partially located in the second component or completely located in the second component. A value that is about X-XX, may mean a value that is between X and XX, inclusive of X and XX. The value(s) between X and XX may be discrete or continuous. The term “about ‘value X’”, or “approximately value X”, as used in the disclosure means within 10 percent of the ‘value X’. For example, a value of about 1 or approximately 1, would mean a value in a range of 0.9-1.1. A “plurality” of components may include all the possible components or only some of the components from all of the possible components. For example, if a device includes ten components, the use of the term “the plurality of components” may refer to all ten components or only some of the components from the ten components.

In some implementations, an interconnect is an element or component of a device or package that allows or facilitates an electrical connection between two points, elements and/or components. In some implementations, an interconnect may include a trace (e.g., trace interconnect), a via (e.g., via interconnect), a pad (e.g., pad interconnect), a pillar, a metallization layer, a redistribution layer, and/or an under bump metallization (UBM) layer/interconnect. In some implementations, an interconnect may include an electrically conductive material that may be configured to provide an electrical path for a signal (e.g., a data signal), ground and/or power. An interconnect may include more than one element or component. An interconnect may be defined by one or more interconnects. An interconnect may include one or more metal layers. An interconnect may be part of a circuit. Different implementations may use different processes and/or sequences for forming the interconnects. In some implementations, a chemical vapor deposition (CVD) process, a physical vapor deposition (PVD) process, a sputtering process, a spray coating, and/or a plating process may be used to form the interconnects.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

In the following, further examples are described to facilitate the understanding of the invention.
Aspect 1: An integrated device comprising a die substrate; a die interconnection portion coupled to the die substrate; a plurality of pad interconnects coupled to the die interconnection portion; a plurality of pillar interconnects coupled to the plurality of pad interconnects; and a plurality of interconnects coupled to the plurality of pillar interconnects, wherein at least one pad interconnect from the plurality of pad interconnects, at least one pillar interconnects from the plurality of pillar interconnects and at least one interconnect from the plurality of interconnects are configured as an inductor.
Aspect 2: The integrated device of aspect 1, wherein the inductor is a solenoid inductor.
Aspect 3: The integrated device of aspects 1 through 2, wherein the die interconnection portion includes a plurality of die interconnects.
Aspect 4: The integrated device of aspect 3, wherein a first plurality of die interconnects from the plurality of die interconnects, at least one pad interconnect from the plurality of pad interconnects, at least one pillar interconnect from the plurality of pillar interconnects and at least one interconnect from the plurality of interconnects are configured as the inductor.
Aspect 5: The integrated device of aspect 4, wherein a second plurality of die interconnects from the plurality of die interconnects is configured as another inductor.
Aspect 6: The integrated device of aspect 5, wherein the another inductor is located between the inductor and the die substrate.
Aspect 7: The integrated device of aspects 1 through 6, further comprising a magnetic layer that at least partially laterally surrounds at least some of the pillar interconnects from the plurality of pillar interconnects.
Aspect 8: The integrated device of aspect 7, further comprising an encapsulation layer that at least partially encapsulates the magnetic layer.
Aspect 9: The integrated device of aspects 1 through 8, further comprising an encapsulation layer that at least partially encapsulates at least some of the pillar interconnects from the plurality of pillar interconnects.
Aspect 10: The integrated device of aspects 1 through 9, further comprising a block component, wherein the block component is surrounded by the inductor.
Aspect 11: A package comprising an integrated device and a substrate coupled to the integrated device through a plurality of solder interconnects. The integrated device comprises a die substrate; a die interconnection portion coupled to the die substrate; a plurality of pad interconnects coupled to the die interconnection portion; a plurality of pillar interconnects coupled to the plurality of pad interconnects; and a plurality of interconnects coupled to the plurality of pillar interconnects, wherein at least one pad interconnect from the plurality of pad interconnects, at least one pillar interconnects from the plurality of pillar interconnects and at least one interconnect from the plurality of interconnects are configured as an inductor.
Aspect 12: The package of aspect 11, wherein the inductor is a solenoid inductor.
Aspect 13: The package of aspects 11 through 12, wherein the die interconnection portion includes a plurality of die interconnects.
Aspect 14: The package of aspect 13, wherein a first plurality of die interconnects from the plurality of die interconnects, at least one pad interconnect from the plurality of pad interconnects, at least one pillar interconnect from the plurality of pillar interconnects and at least one interconnect from the plurality of interconnects are configured as the inductor.
Aspect 15: The package of aspect 14, wherein a second plurality of die interconnects from the plurality of die interconnects is configured as another inductor.
Aspect 16: The package of aspect 15, wherein the another inductor is located between the inductor and the die substrate.
Aspect 17: The package of aspects 11 through 16, wherein the integrated device further comprises a magnetic layer that at least partially laterally surrounds at least some of the pillar interconnects from the plurality of pillar interconnects.
Aspect 18: The package of aspect 17, wherein the integrated device further comprises an encapsulation layer.
Aspect 19: The package of aspects 11 through 18, wherein the integrated device further comprises a block component, wherein the block component is surrounded by the inductor.
Aspect 20: The package of aspects 11 through 19, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

1. An integrated device comprising:
a die substrate;
a die interconnection portion coupled to the die substrate;
a plurality of pad interconnects coupled to the die interconnection portion;
a plurality of pillar interconnects coupled to the plurality of pad interconnects; and
a plurality of interconnects coupled to the plurality of pillar interconnects,
wherein at least one pad interconnect from the plurality of pad interconnects, at least one pillar interconnects from the plurality of pillar interconnects and at least one interconnect from the plurality of interconnects are configured as an inductor.

2. The integrated device of claim 1, wherein the inductor is a solenoid inductor.

3. The integrated device of claim 1, wherein the die interconnection portion includes a plurality of die interconnects.

4. The integrated device of claim 3, wherein a first plurality of die interconnects from the plurality of die interconnects, at least one pad interconnect from the plurality of pad interconnects, at least one pillar interconnect from the plurality of pillar interconnects and at least one interconnect from the plurality of interconnects are configured as the inductor.

5. The integrated device of claim 4, wherein a second plurality of die interconnects from the plurality of die interconnects is configured as another inductor.

6. The integrated device of claim 5, wherein the another inductor is located between the inductor and the die substrate.

7. The integrated device of claim 1, further comprising a magnetic layer that at least partially laterally surrounds at least some of the pillar interconnects from the plurality of pillar interconnects.

8. The integrated device of claim 7, further comprising an encapsulation layer that at least partially encapsulates the magnetic layer.

9. The integrated device of claim 1, further comprising an encapsulation layer that at least partially encapsulates at least some of the pillar interconnects from the plurality of pillar interconnects.

10. The integrated device of claim 1, further comprising a block component, wherein the block component is surrounded by the inductor.

11. A package comprising:
an integrated device comprising:
a die substrate;
a die interconnection portion coupled to the die substrate;
a plurality of pad interconnects coupled to the die interconnection portion;
a plurality of pillar interconnects coupled to the plurality of pad interconnects; and
a plurality of interconnects coupled to the plurality of pillar interconnects,
wherein at least one pad interconnect from the plurality of pad interconnects, at least one pillar interconnects from the plurality of pillar interconnects and at least one interconnect from the plurality of interconnects are configured as an inductor; and
a substrate coupled to the integrated device through a plurality of solder interconnects.

12. The package of claim 11, wherein the inductor is a solenoid inductor.

13. The package of claim 11, wherein the die interconnection portion includes a plurality of die interconnects.

14. The package of claim 13, wherein a first plurality of die interconnects from the plurality of die interconnects, at least one pad interconnect from the plurality of pad interconnects, at least one pillar interconnects from the plurality of pillar interconnect and at least one interconnect from the plurality of interconnects are configured as the inductor.

15. The package of claim 14, wherein a second plurality of die interconnects from the plurality of die interconnects is configured as another inductor.

16. The package of claim 15, wherein the another inductor is located between the inductor and the die substrate.

17. The package of claim 11, wherein the integrated device further comprises a magnetic layer that at least partially laterally surrounds at least some of the pillar interconnects from the plurality of pillar interconnects.

18. The package of claim 17, wherein the integrated device further comprises an encapsulation layer.

19. The package of claim 11, wherein the integrated device further comprises a block component, wherein the block component is surrounded by the inductor.

20. The package of claim 11, wherein the package is incorporated in a device from a group consisting one of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, an internet of things (IoT) device, and a device in an automotive vehicle.
